(19) United States
(12) Patent Application Publication
(10) Pub. No.: US 2025/0380563 A1
(43) Pub. Date: Dec. 11, 2025

(54) DISPLAY DEVICE AND ELECTRONIC DEVICE HAVING THE SAME

(71) Applicant: Samsung Display Co., LTD., Yongin-si (KR)

(72) Inventors: Sun Kwun SON, Yongin-si (KR); Dong Hee SHIN, Yongin-si (KR); Na Hyeon CHA, Yongin-si (KR)

(21) Appl. No.: 19/076,749

(22) Filed: Mar. 11, 2025

(30) Foreign Application Priority Data
Jun. 5, 2024 (KR) 10-2024-0073425

(51) Int. Cl. H10K 39/34; H10K 59/121

(52) U.S. Cl. CPC H10K 39/34; H10K 59/121

(57) ABSTRACT

A display device includes: a substrate; an element layer on the substrate, the element layer including a first light receiving element including a first light receiving layer, a second light receiving element including a second light receiving layer, and a third light receiving element including a third light receiving layer; and a selective light transmitting layer on the element layer, the selective light transmitting layer including openings forming an advancing path of light incident onto the first to third light receiving elements and a light blocking pattern between the openings, wherein, in a plan view, at least a portion of the light blocking pattern overlaps with the second light receiving layer and the third light receiving layer.

### CROSS-REFERENCE TO RELATED APPLICATION

The present application claims priority to and the benefit of Korean patent application No. 10-2024-0073425, filed on Jun. 5, 2024, in the Korean Intellectual Property Office, the entire disclosure of which is incorporated herein by reference.

### BACKGROUND

### 1. Field

Aspects of some embodiments of the present disclosure relate to a display device and an electronic device having the same.

### 2. Description of the Related Art

Recently, as interest in information displays is increased, research, and development of display devices have been continuously conducted.

The above information disclosed in this Background section is only for enhancement of understanding of the background and therefore the information discussed in this Background section does not necessarily constitute prior art.

### SUMMARY

Aspects of some embodiments include a pixel and a display device having relatively improved reliability and an electronic device having the same.

Aspects of some embodiments of the present disclosure include a display device including a substrate; an element layer on the substrate, the element layer including a first light receiving element including a first light receiving layer, a second light receiving element including a second light receiving layer, and a third light receiving element including a third light receiving layer; and a selective light transmitting layer on the element layer, the selective light transmitting layer including openings forming an advancing path of light incident onto the first to third light receiving elements and a light blocking pattern between the openings. In a plan view, at least a portion of the light blocking pattern overlaps with the second light receiving layer and the third light receiving layer.

According to some embodiments, the second light receiving element may include a first sub-light receiving element and a second sub-light receiving element, which are electrically connected to each other through a first routing line extending in a first direction. According to some embodiments, the third light receiving element may include a third sub-light receiving element and a fourth sub-light receiving element, which are electrically connected to each other through a second routing line extending in the first direction. According to some embodiments, the first sub-light receiving element and the third sub-light receiving element may be located on the same column in a second direction, and the second sub-light receiving element and the fourth sub-light receiving element may be located on the same column in the second direction.

According to some embodiments, the element layer may further include first light emitting elements each including a first light emitting layer, second light emitting elements each including a second light emitting layer, and third light emitting elements each including a third light emitting layer. According to some embodiments, in a plan view, at least one third light emitting element among the third light emitting elements may be located between the first sub-light receiving element and the second sub-light receiving element in the first direction. According to some embodiments, in a plan view, at least another third light emitting element among the third light emitting elements may be located between the third sub-light receiving element and the fourth sub-light receiving element in the first direction. According to some embodiments, the at least one third light emitting element and the at least another third light emitting element may be located on the same column in the second direction.

According to some embodiments, the openings may include: a first opening corresponding to the first light receiving element; a second opening corresponding to the second light receiving element; a third opening corresponding to the third light receiving element; a fourth opening corresponding to each of the first light emitting elements; a fifth opening corresponding to each of the second light emitting elements; and a sixth opening corresponding to each of the third light emitting elements. According to some embodiments, the second opening may include a (2-1)th opening corresponding to the first sub-light receiving element and a (2-2)th opening corresponding to the second sub-light receiving element. According to some embodiments, the third opening may include a (3-1)th opening corresponding to the third sub-light receiving element and a (3-2)th opening corresponding to the fourth sub-light receiving element. According to some embodiments, the sixth opening may include a (6-1)th opening corresponding to the at least one third light emitting element and a (6-2)th opening corresponding to the at least another third light emitting element.

According to some embodiments, in a plan view, a first shortest distance between the (2-1)th opening and the (6-1)th opening may be smaller than a second shortest distance between the (3-1)th opening and the (6-2)th opening.

According to some embodiments, in a plan view, a third shortest distance between the (2-2)th opening and the (6-1)th opening may be greater than a fourth shortest distance between the (3-2)th opening and the (6-2)th opening.

According to some embodiments, the first shortest distance and the fourth shortest distance may be the same, and the second shortest distance and the third shortest distance may be the same.

According to some embodiments, in a plan view, the (2-1)th opening may be located more adjacent to the (6-1)th opening than the (2-2)th opening.

According to some embodiments, in a plan view, the (3-2)th opening may be located more adjacent to the (6-2)th opening than the (3-1)th opening.

According to some embodiments, in a plan view, an edge of the (2-1)th opening may be located inwardly of an edge of the (3-1)th opening in the first direction.

According to some embodiments, in a plan view, an edge of the (2-2)th opening may be located inwardly of an edge of the (3-2)th opening in the first direction.

According to some embodiments, the second opening and the third opening may have a circular shape.

According to some embodiments, in a plan view, a center of the second opening and a center of the third opening may be shifted in directions opposite to each other along the first direction.

According to some embodiments, in a plan view, each of the first to fourth sub-light receiving elements may be located between two adjacent second light emitting elements among the second light emitting elements in the second direction. According to some embodiments, the two second light emitting elements may include a (2-1)th light emitting element located at an upper side of each of the first to fourth sub-light receiving elements in the second direction and a (2-2)th light emitting element located at a lower side of each of the first to fourth sub-light receiving elements in the second direction.

According to some embodiments, the fifth opening may include a (5-1)th opening corresponding to the (2-1)th light emitting element and a (5-2)th opening corresponding to the (2-2)th light emitting element. According to some embodiments, in a plan view, a first distance between each of the (2-1)th and (2-2)th openings and the (5-1)th opening in the second direction may be smaller than a second distance between each of the (2-1)th and (2-2)th openings and the (5-2)th opening in the second direction. According to some embodiments, in a plan view, a third distance between each of the (3-1)th and (3-2)th openings and the (5-1)th opening in the second direction may be greater than a fourth distance between each of the (3-1)th and (3-2)th openings and the (5-2)th opening in the second direction.

According to some embodiments, the first distance and the fourth distance may be the same, and the second distance and the third distance may be the same.

According to some embodiments, in a plan view, each of the (2-2)th and (2-2)th openings may be located more adjacent to the (5-1)th opening than the (5-2)th opening. According to some embodiments, in a plan view, each of the (3-1)th and (3-2)th openings may be located more adjacent to the (5-2)th opening than the (5-1)th opening.

According to some embodiments, the element layer may further include first light emitting elements each including a first light emitting layer, second light emitting elements each including a second light emitting layer, and third light emitting elements each including a third light emitting layer. According to some embodiments, in a plan view, at least one second light emitting element among the second light emitting elements may be located between the first sub-light receiving element and the second sub-light receiving element in the first direction. According to some embodiments, in a plan view, at least another second light emitting element among the second light emitting elements may be located between the third sub-light receiving element and the fourth sub-light receiving element in the first direction. According to some embodiments, the at least one second light emitting element and the at least another second light emitting element may be located on the same column in the second direction.

According to some embodiments, the openings may include: a first opening corresponding to the first light receiving element; a second opening corresponding to the second light receiving element; a third opening corresponding to the third light receiving element; a fourth opening corresponding to each of the first light emitting elements; a fifth opening corresponding to each of the second light emitting elements; and a sixth opening corresponding to each of the third light emitting elements. According to some embodiments, the second opening may include a (2-1)th opening corresponding to the third sub-light receiving element and a (2-2)th opening corresponding to the second sub-light receiving element. According to some embodiments, the third opening may include a (3-1)th opening corresponding to the third sub-light receiving element and a (3-2)th opening corresponding to the fourth sub-light receiving element. According to some embodiments, the fifth opening may include a (5-1)th opening corresponding to the at least one second light emitting element and a (5-2)th opening corresponding to the at least another second light emitting element.

According to some embodiments, in a plan view, a first shortest distance between the (2-1)th opening and the (5-1)th opening may be smaller than a second shortest distance between the (3-1)th opening and the (5-2)th opening. According to some embodiments, in a plan view, a third shortest distance between the (2-2)th opening and the (5-1)th opening may be greater than a fourth shortest distance between the (3-2)th opening and the (5-2)th opening.

According to some embodiments, in a plan view, the first light receiving layer may not overlap with the light blocking pattern.

According to some embodiments of the present disclosure, an electronic device includes: a processor configured to provide input image data to a display device; and the display device configured to display an image, based on the input image data, wherein the display device includes: a substrate; an element layer on the substrate, the element layer including a first light receiving element including a first light receiving layer, a second light receiving element including a second light receiving layer, and a third light receiving element including a third light receiving layer; and a selective light transmitting layer on the element layer, the selective light transmitting layer including openings forming an advancing path of light incident onto the first to third light receiving elements and a light blocking pattern between the openings. According to some embodiments, in a plan view, at least a portion of the light blocking pattern overlaps with the second light receiving layer and the third light receiving layer. According to some embodiments, the second light receiving layer includes a first sub-light receiving element and a second sub-light receiving element, which are electrically connected to each other through a first routing line extending in a first direction. According to some embodiments, the third light receiving layer includes a third sub-light receiving element and a fourth sub-light receiving element, which are electrically connected to each other through a second routing line extending in the first direction. According to some embodiments, the first sub-light receiving element and the third sub-light receiving element are located on the same column in a second direction, and the second sub-light receiving element and the fourth sub-light receiving element are located on the same column in the second direction.

According to some embodiments, the openings may include: a first opening corresponding to the first light receiving element; a second opening corresponding to the second light receiving element; and a third opening corresponding to the third light receiving element. According to some embodiments, in a plan view, a center of the second opening and a center of the third opening may be shifted in directions opposite to each other along the first direction.

According to some embodiments, in a plan view, the first light receiving layer may not overlap with the light blocking pattern.

### BRIEF DESCRIPTION OF THE DRAWINGS

Aspects of some embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic block diagram illustrating a display device according to some embodiments of the present disclosure.

FIG. 2 is a schematic block diagram illustrating further details of the display device shown in FIG. 1 according to some embodiments.

FIG. 3 is a schematic diagram illustrating aspects of an arrangement of pixel circuits and sensor circuits of a display area of a display panel included in the display device shown in FIG. 2 according to some embodiments.

FIG. 4 is a schematic diagram illustrating aspects of the display area of the display panel included in the display device shown in FIG. 2 according to some embodiments.

FIG. 5 is a schematic diagram illustrating aspects of the arrangement of the pixel circuits and the sensor circuits of the display area of the display panel included in the display device shown in FIG. 2 according to some embodiments.

FIG. 6 is a schematic circuit diagram illustrating aspects of a sub-pixel and a light sensing pixel, which are included in a display area shown in FIG. 1 according to some embodiments.

FIG. 7 is a schematic cross-sectional view illustrating one area of the display device according to some embodiments of the present disclosure.

FIG. 8 is a schematic cross-sectional view illustrating a reflection path of light in the display device shown in FIG. 7 according to some embodiments.

FIG. 9 is a schematic plan view illustrating one area of a display area of a display device according to some embodiments of the present disclosure.

FIG. 10 is a schematic plan view illustrating one area of the display area of the display device, in which some components are omitted in FIG. 9.

FIG. 11 is a schematic plan view illustrating a selective light transmitting layer shown in FIG. 10.

FIG. 12 is a schematic cross-sectional view taken along the line I-I′ shown in FIG. 9.

FIG. 13 is a schematic cross-sectional view illustrating only some components in FIG. 12.

FIG. 14 is a schematic cross-sectional view taken along the line II-II′ shown in FIG. 9.

FIG. 15 is a schematic cross-sectional view taken along the line III-III′ shown in FIG. 9.

FIG. 16 is a schematic plan view illustrating one area of a display area of a display device according to some embodiments of the present disclosure.

FIG. 17 is a schematic plan view illustrating a selective light transmitting layer shown in FIG. 16.

FIG. 18 is a schematic plan view illustrating one area of a display area of a display device according to some embodiments of the present disclosure.

FIG. 19 is a schematic block diagram illustrating an electronic device according to some embodiments of the present disclosure.

FIG. 20 is a schematic view illustrating an example in which the electronic device shown in FIG. 19 is implemented as a smartphone.

FIG. 21 is a schematic view illustrating an example in which the electronic device shown in FIG. 19 is implemented as a tablet PC.

### DETAILED DESCRIPTION

The present disclosure may apply various changes and different shape, therefore only illustrate in details with particular examples. However, the examples do not limit to certain shapes but apply to all the change and equivalent material and replacement. The drawings included are illustrated a fashion where the figures are expanded for the better understanding.

Like numbers refer to like elements throughout. In the drawings, the thickness of certain lines, layers, components, elements or features may be exaggerated for clarity. It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

Hereinafter, aspects of some embodiments of the present disclosure will be described in more detail with reference to the accompanying drawings. In the following description, singular forms in the present disclosure are intended to include the plural forms as well, unless the context clearly indicates otherwise.

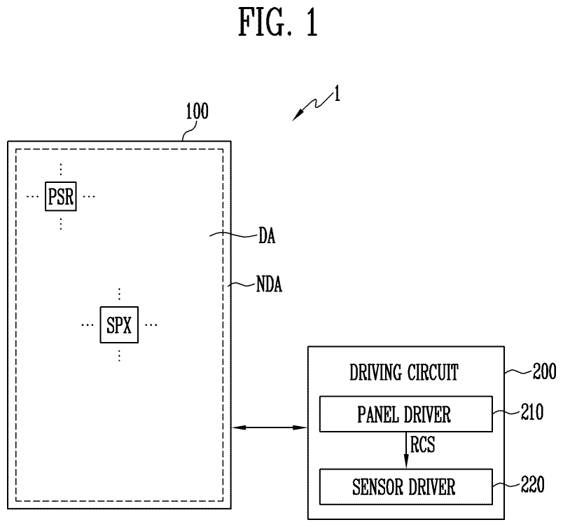

FIG. 1 is a schematic block diagram illustrating a display device 1 according to some embodiments of the present disclosure.

Referring to FIG. 1, the display device 1 according to some embodiments of the present disclosure may include a display panel 100 and a driving circuit 200. According to some embodiments, the driving circuit 200 may include a panel driver 210 and a sensor driver 220.

The display device 1 may be implemented as a self-luminous display device including a plurality of self-luminous elements. For example, the display device 1 may be an organic light emitting display device including an organic light emitting element. However, embodiments according to the present disclosure are not limited thereto, and the display device 1 may be implemented as a display device including an inorganic light emitting element, a display device including light emitting elements configured with a combination of an inorganic material and an organic material, a display device which displays an image, using a quantum dot, or the like.

The display device 1 may be a flat panel display device, a flexible display device, a curved display device, a foldable display device, a bendable display device, or a rollable display device. Also, the display device 1 may be applied to a transparent display device, a head-mounted display device, a wearable display device, and the like.

The display panel 100 may include a display area DA and a non-display area NDA. The display area DA may be an area in which at least one sub-pixel SPX (or pixel) is provided. The sub-pixel SPX may include at least one light emitting element. For example, the light emitting element may include a light emitting layer (e.g., an organic light emitting layer). A portion at which light is emitted by the light emitting element may be defined as an emission area. The display device 1 may drive the sub-pixel SPX, thereby displaying images in the display area DA.

The non-display area NDA may be an area provided at the periphery (e.g. surrounding or outside a footprint) of the display area DA. According to some embodiments, the non-display area NDA may inclusively mean the other area except the display area DA on the display panel 100. For example, the non-display area NDA may include a line area, a pad area, various dummy areas, and the like.

At least one light sensing pixel PSR may be included in the display area DA. The light sensing pixel PSR may be referred to as a photo sensor. The light sensing pixel PSR may include a light receiving element including a light receiving layer. The light receiving layer of the light receiving element may be arranged while being spaced apart from the light emitting layer of the light emitting element in the display area DA.

A plurality of light sensing pixels PSR may be distributed while being spaced apart from each other throughout the entire area of the display area DA. However, embodiments according to the present disclosure are not limited thereto. Only one area of the display area DA may be set as a sensing area (e.g., a set or predetermined sensing area), and light sensing pixels PSR may be provided in the corresponding sensing area. Light sensing pixels SPR may be provided in at least a portion of the non-display area NDA.

The light sensing pixel PSR may sense that light output from a light source (e.g., the light emitting element of the sub-pixel SPX) is reflected by an external object (e.g., a finger of a user, or the like). For example, a fingerprint of the user may be sensed through the light sensing pixel PSR. Hereinafter, a case where the light sensing pixel PSR is used for fingerprint sensing will be described as an example. However, in various embodiments, the light sensing pixel SPR may sense various biometric information such as an iris and a vein.

The driving circuit 200 may include the panel driver 210 and the sensor driver 220. The panel driver 210 and the sensor driver 220 may be implemented as integrated circuits independent from each other. According to some embodiments, the driving circuit 200 may be implemented as one integrated circuit. At least a portion of the sensor driver 220 may be included in the panel driver 210, or operate in connection with the panel driver 210.

The panel driver 210 may scan the sub-pixel SPX of the display area DA, and supply, to the sub-pixel SPX, a data signal corresponding to image data (or an image). The display panel 100 may display an image corresponding to the data signal.

The panel driver 210 may supply a driving signal for light sensing (e.g., fingerprint sensing) to the sub-pixel SPX. The driving signal may be provided to allow the sub-pixel SPX to emit light, thereby operating as a light source for the light sensing pixel PSR. The panel driver 210 may supply the driving signal for photo sensing and/or another driving signal to the light sensing pixel PSR. However, embodiments according to the present disclosure are not limited thereto, and driving signals for light sensing may be supplied to the light sensing pixel PSR by the sensor driver 220.

The sensor driver 220 may detect biometric information such as a finger of the user, based on a sensing signal received from the light sensing pixel PSR. According to some embodiments, the sensor driver 220 may supply the driving signals to the light sensing pixel PSR and/or the sub-pixel SPX.

The panel driver 210 may provide a readout control signal to the sensor driver 220, and the sensor driver 220 may read out (or sample) a sensing signal in connection with the panel driver 210, based on the readout control signal RCS. For example, the sensor driver 220 may read out or sample the sensing signal in at least one pixel row (or horizontal line) unit in response to the readout control signal RCS.

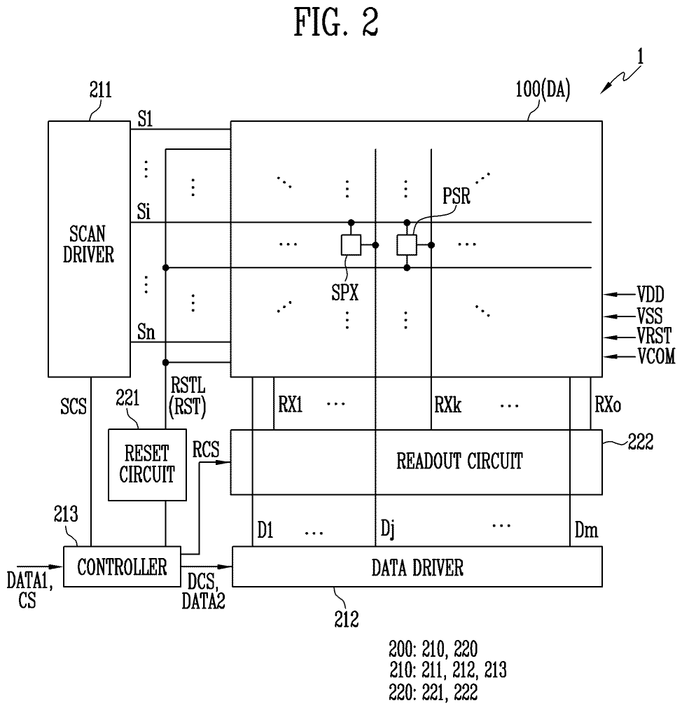

FIG. 2 is a schematic block diagram illustrating aspects of the display device 1 shown in FIG. 1 according to some embodiments.

Referring to FIGS. 1 and 2, the display device 1 may include a display panel 100 and a driving circuit 200.

The display panel 100 may include signal lines, sub-pixels SPX, and light sensing pixels PSR. Although FIG. 2 illustrates a single sub-pixel SPX and a single light sensing pixel PSR, as a person having ordinary skill in the art would appreciate, the display panel 100 may have any suitable number of sub-pixels SPX and light sensing pixels PSR according to the design and size of the display panel 100.

The signal lines may include scan lines S1 to Sn, data lines D1 to Dm, readout lines RX1 to RXo, and a reset line RSTL (or reset control line) (each of n, m, and o may be a natural number).

The sub-pixels SPX may be located in areas (e.g., pixel areas) partitioned by the scan lines S1 to Sn and the data lines D1 to Dm. The light sensing pixels PSR may be located in areas partitioned by the scan lines S1 to Sn and the readout lines RX1 to RXo. The sub-pixels SPX and the light sensing pixels PSR may be arranged in a two-dimensional array in a display area DA of the display panel 100, but embodiments according to the present disclosure are not limited thereto.

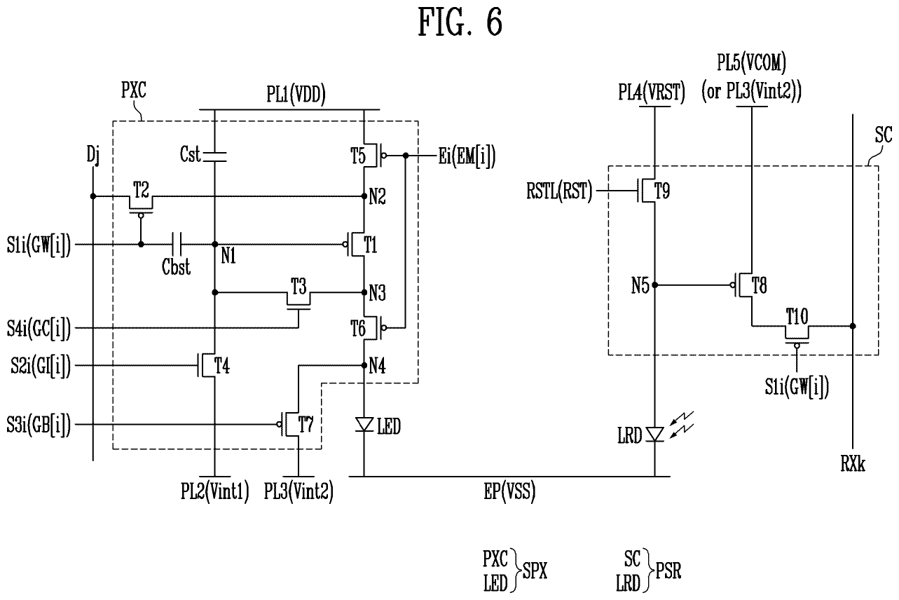

The sub-pixel SPX may be electrically connected to at least one of the scan lines S1 to Sn and at least one of the data lines D1 to Dm. The light sensing pixel PSR may be electrically connected to one of the scan lines S1 to Sn, one of the readout lines RX1 to RXo, and the reset line RSTL. A connection configuration between the sub-pixel SPX, the light sensing pixel PSR, and the signal lines will be described in more detail later with reference to FIG. 6.

Power voltages VDD, VSS, VRST, and VCOM necessary for driving of the sub-pixel SPX and the light sensing pixel PSR may be provided to the display panel 100. The power voltages VDD, VSS, VRST, and VCOM may be supplied from a power supply. The power supply may be implemented as a Power Management IC (PMIC).

The driving circuit 200 may include a scan driver 211, a data driver 212, a controller 213, a reset circuit 221, and a readout circuit 222. For example, the scan driver 211, the data driver 212, and the controller 213 may be included in a panel driver 210, and the reset circuit 221 and the readout circuit 222 may be included in a sensor driver 220. However, embodiments according to the present disclosure are not limited thereto. According to some embodiments, the reset circuit 221 may be included in the panel driver 210.

The scan driver 211 may be electrically connected to the sub-pixels SPX and the light sensing pixels PSR through the scan lines S1 to Sn. The scan driver 211 may generate scan signals, based on a scan control signal SCS, and supply the scan signal to the scan lines S1 to Sn. The scan control signal SCS may include a start signal, clock signals, and the like, and be provided from the controller 213 to the scan driver 211. For example, the scan driver 211 may be implemented as a shift register which generates and outputs scan signals by sequentially shifting the start signal in a pulse form, using the clock signals. The scan driver 211 may selectively drive the sub-pixel SPX and the light sensing pixel PSR while scanning the display panel 100.

The scan driver 211 may be formed together with the sub-pixels SPX of the display panel 100, but embodiments according to the present disclosure are not limited thereto. According to some embodiments, the scan driver 211 may be implemented as an integrated circuit.

A sub-pixel SPX selectively driven by the scan driver 211 may emit light with a luminance corresponding to a data signal provided to a corresponding data line among the data lines D1 to Dm. The light sensing pixel PSR selectively driven by the scan driver 211 may output, to a corresponding readout line, an electrical signal (e.g., a sensing signal) corresponding to sensed light. For example, a sub-pixel SPX selectively driven through an ith scan line Si may emit light with a luminance corresponding to a data signal supplied to a jth data line Dj (i and j are natural numbers). For example, a light sensing pixel PSR selectively driven through the ith scan line Si may output an electrical signal corresponding to sensed light to a kth readout line RXk (k is a natural number).

The data driver 212 may generate a data signal (or data voltage), based on image data DATA2 and a data control signal DCS, which are provided from the controller 213, and supply the data signal to the display panel 100 (or the sub-pixels SPX) through the data lines D1 to Dm. The data control signal DCS may be a signal for controlling an operation of the data driver 212, and include a horizontal start signal, a data clock signal, and the like. For example, the data driver 212 may include a shift register which generates a sampling signal by shifting the horizontal start signal in synchronization with the data clock signal, a latch which latches the image data DATA2 in response to the sampling signal, a digital-analog converter (or decoder) which converts the latched image data (e.g., data in a digital form) into a data signal in an analog form, and a buffer (or amplifier) which outputs the data signal to a corresponding data line (e.g., the jth data line Dj).

The controller 213 may receive input image data DATA1 and a control signal CS from an external device (e.g., a graphic processor, an application processor, or a first processor), generate the scan control signal SCS and the data control signal DCS, based on the control signal CS, and generate the image data DATA2 by converting the input image data DATA1. The control signal CS may include a vertical synchronization signal, a horizontal synchronization signal, a reference clock signal, and the like. The vertical synchronization signal may represent a start of frame data (i.e., data corresponding to a frame period in which one frame image is displayed), and the horizontal synchronization signal may represent a start of a data row (i.e., one data row among a plurality of data rows included in frame data). The controller 213 may convert the input image data DATA1 into the image data DATA2 having a format corresponding to a pixel arrangement in the display panel 100.

Also, the controller 213 may generate a reset control signal and a readout control signal RCS, based on the control signal CS.

The reset circuit 221 may be commonly connected to all the light sensing pixels PSR provided in the display panel 100 through one reset line RSTL. The reset circuit 221 may simultaneously supply a reset signal RST to all the light sensing pixels PSR in response to the reset control signal. Because the reset signal RST is simultaneously supplied to all the light sensing pixels PSR, the reset signal RST may be referred to as a global reset signal.

The readout circuit 222 may receive a sensing signal from the light sensing pixel PSR through the readout lines RX1 to RXo, and perform signal processing on the sensing signal.

For example, the readout circuit 222 may perform a Correlated Double Sampling (CDS) operation for removing noise from a sensing signal provided from the light sensing pixel PSR. A timing of the CDS operation of the readout circuit 222 may be determined by the readout control signal RCS. The readout circuit 222 may convert the sensing signal in an analog form into a signal (or digital value) in a digital form. A configuration for CDS and analog-digital conversion may be provided with respect to the readout lines RX1 to RXo, and the readout circuit 222 may process, in parallel, sensing signals provided from the readout lines RX1 to RSo.

The processed sensing signals, i.e., readout sensing signals may transferred as one sensing data (or biometric information) to an external device (e.g., an application processor), and biometric authentication (e.g., fingerprint authentication or the like) may be performed based on the sensing data. According to some embodiments, the readout sensing signals may be supplied to the controller 213, and the biometric authentication may be performed in the controller 213.

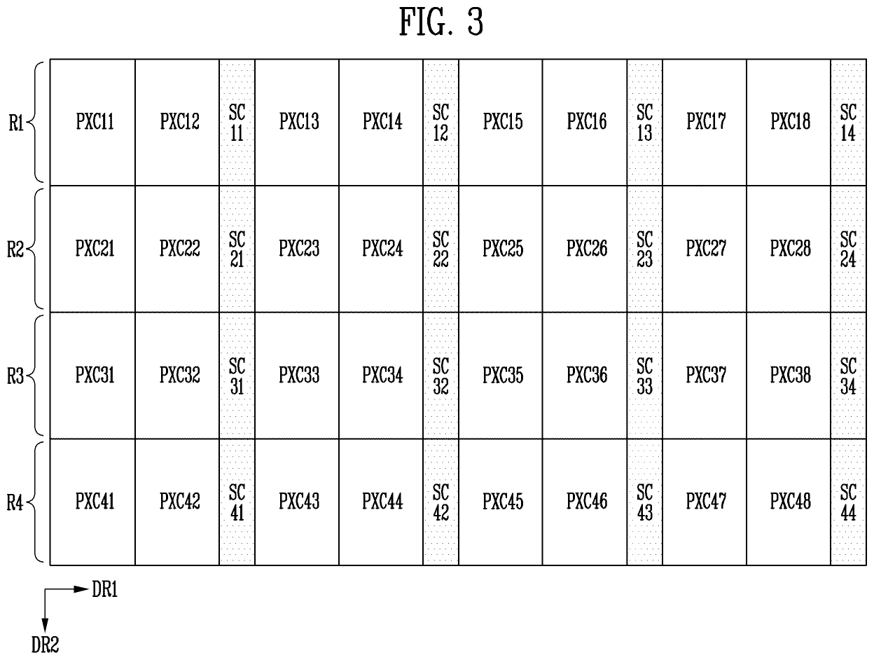

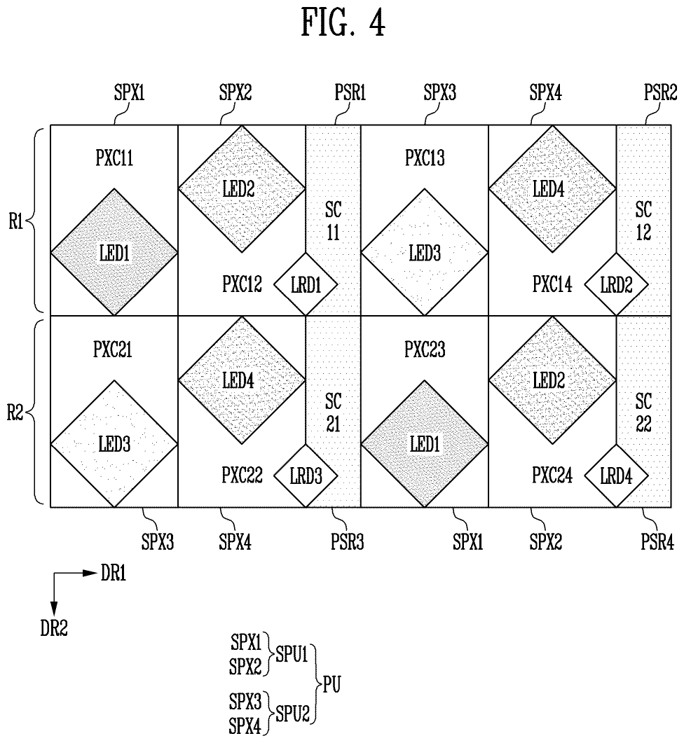

FIG. 3 is a schematic diagram illustrating an example of an arrangement of pixel circuits and sensor circuits of the display area of the display panel included in the display device shown in FIG. 2. FIG. 4 is a schematic diagram illustrating an example of the display area of the display panel included in the display device shown in FIG. 2.

Referring to FIGS. 1 to 4, sub-pixels SPX1 to SPX4 and a plurality of light sensing pixels SPR1 to SPR4 may be located in the display area (see “DA” shown in FIG. 1) of the display panel (see “100” shown in FIG. 1).

The display area DA may be divided into pixel rows R1 to R4. Each of the pixel rows R1 to R4 may extend in a first direction DR1, and be arranged in a second direction DR2. Each of the pixel rows R1 to R4 may include sub-pixels SPX1 to SPX4. Each of the sub-pixels SPX1 to SPX4 may include one of pixel circuits PXC11 to PXC 48 and one of light emitting elements LED1 to LED4.

According to some embodiments, a first sub-pixel SPX1, a second sub-pixel SPX2, and a third sub-pixel SPX3 may emit light of a first color, light of a second color, and light of a third color, respectively. The light of the first color, the light of the second color, and the light of the third color may be lights of different colors. For example, each of the light of the first color, the light of the second color, and the light of the third color may be one of red light, green light, and blue light. A first light emitting element LED1 emitting the light of the first color may be located in the first sub-pixel SPX1, a second light emitting element LED2 emitting the light of the second color may be located in the second sub-pixel SPX2, a third light emitting element LED3 emitting the light of the third color may be located in the third sub-pixel SPX3, and a fourth light emitting element LED4 emitting the light of the second color may be located in a fourth sub-pixel SPX4. The second light emitting element LED2 and the fourth light emitting element LED4 may emit light of the same color.

In FIG. 4, each of the light emitting elements LED1 to LED4 may be understood as an emission area corresponding to a light emitting layer. However, this is for convenience of description, and the color of light emitted by each of the light emitting elements LED1 to LED4 and the position, area, shape, and the like of each of the light emitting elements LED1 to LED4, and the like are not be limited thereto.

According to some embodiments, sub-pixels SPX1 to SPX4 may be arranged with respect to the first direction DR1 in an order of a first sub-pixel SPX1 emitting red light, a second sub-pixel SPX2 emitting green light, a third sub-pixel SPX3 emitting blue light, and a fourth sub-pixel SPX4 emitting green light on each of odd-numbered pixel rows including a first pixel row R1 (or first horizontal line) and a third pixel row R3 (or third horizontal line).

Sub-pixels SPX1 to SPX4 may be arranged with respect to the first direction DR1 in an order of a third sub-pixel SPX3, a fourth sub-pixel SPX4, a first sub-pixel SPx1, and a second sub-pixel SPX2 on each of even-numbered pixel rows including a second pixel row R2 (or second horizontal line) and a fourth pixel row R4 (or fourth horizontal line).

According to some embodiments, the first sub-pixel SPX1 and the second sub-pixel SPX2 may constitute a first sub-pixel unit SPU1, and the third sub-pixel SPX3 and the fourth sub-pixel SPX4 may constitute a second sub-pixel unit SPU2. The first sub-pixel unit SPU1 and the second sub-pixel unit SPU2 may be alternately arranged on the odd-numbered pixel rows R1 and R3, and the second sub-pixel unit SPU2 and the first sub-pixel unit SPU2 may be alternately arranged on the even-numbered pixel rows R2 and R4 on the contrary to the odd-numbered pixel rows R1 and R3.

It may be understood that predetermined first and second sub-pixel units SPU1 and SPU2 adjacent to each other constitute one pixel unit PU. For example, FIG. 4 illustrates a pixel unit PU of each of the first pixel row R1 and the second pixel row R2. However, embodiments according to the present disclosure are not limited thereto, and the arrangement of sub-pixels SPX1 to SPX4 may be variously changed.

Pixel circuits PXC11 to PXC18 respectively corresponding to sub-pixels SPX1 to SPX4 of the first pixel row R1 may be arranged in the first direction DR1 on the first pixel row R1. Pixel circuits PXC21 to PXC28 respectively corresponding to sub-pixels SPX1 to SPX4 of the second pixel row R2 may be arranged in the first direction DR1 on the second pixel row R2. Pixel circuits PXC31 to PXC38 respectively corresponding to sub-pixels SPX1 to SPX4 of the third pixel row R3 may be arranged in the first direction DR1 on the third pixel row R3. Pixel circuits PXC41 to PXC48 respectively corresponding to sub-pixels SPX1 to SPX4 of the fourth pixel row R4 may be arranged in the first direction DR1 on the fourth pixel row R4.

In FIG. 3, first, second, third, and fourth pixel circuits PXC11, PXC12, PXC13, and PXC14 of the first pixel row R1 may be included in one pixel unit PU, and fifth, sixth, seventh, and eighth pixel circuits PXC15, PXC16, PXC17, and PXC18 of the first pixel row R1 may be included in another pixel unit PU.

Similarly to this, first to fourth pixel circuits PXC21 to PXC24 of the second pixel row R2, fifth to eighth pixel circuits PXC25 to PXC28 of the second pixel row R2, first to fourth pixel circuits PXC31 to PXC34 of the third pixel row R3, fifth to eighth pixel circuits PXC35 to PXC38 of the third pixel row R3, first to fourth pixel circuits PXC41 to PXC44 of the fourth pixel row R4, and fifth to eighth pixel circuits PXC45 to PXC48 of the fourth pixel row R4 may also be included in different pixel units PU.

According to some embodiments, the pixel rows R1 to R4 may include light receiving elements LRD1 to LRD4. In FIG. 4, each of the light receiving elements LRD1 to LRD4 may be understood as a light receiving area corresponding to a light receiving layer. However, this is for convenience of description, and the position, area, shape, and the like of each of the light receiving elements LRD1 to LRD4 may be variously changed.

Light receiving elements LRD1 and LRD2 of the first pixel row R1 may overlap with at least portions of the pixel circuits PXC11 to PXC14 of the first pixel row R1 and sensor circuits SC11 and SC12 of the first pixel row R1, respectively. Light receiving elements LRD3 and LRD4 of the second pixel row R2 may overlap with at least portions of the pixel circuits PXC21 to PXC24 of the second pixel row R2 and sensor circuits SC21 and SC22 of the second pixel row R2, respectively.

According to some embodiments, a first light receiving element LRD1 may overlap with at least a portion of a first sensor circuit SC11 of the first pixel row R1, and a third light receiving element LRD3 may overlap with at least a portion of a first sensor circuit SC21 of the second pixel row R2.

A second light receiving element LRD2 may overlap with at least a portion of a second sensor circuit SC12 of the first pixel row R1, and a fourth light receiving element LRD4 may overlap with at least a portion of a second sensor circuit SC22 of the second pixel row R2.

The light receiving elements LRD1 to LRD4 may be formed in the same arrangement in the display area DA as shown in FIG. 4, but embodiments according to the present disclosure are not limited thereto.

According to some embodiments, each of sensor circuits SC11 to SC44 may be electrically connected to a corresponding light receiving element. The first sensor circuit SC11 of the first pixel row R1 may be electrically connected to the first light receiving element LRD1 to constitute a first light sensing pixel PSR1. That is, the first sensor circuit SC11 and the first light emitting element LRD1 may constitute the first light sensing pixel PSR1. The second sensor circuit SC12 of the first pixel row R1 may be electrically connected to the second light receiving element LRD2 to constitute a second light sensing pixel PSR2. That is, the second sensor circuit SC12 and the second light receiving element LRD2 may constitute the second light sensing pixel PSR2. The first sensor circuit SC21 of the second pixel row R2 may be electrically connected to the third light receiving element LRD3 to constitute a third light sensing pixel PSR3. That is, the first sensor circuit S21 and the third light receiving element LRD3 may constitute the third light sensing pixel PSR3. The second sensor circuit SC22 of the second pixel row R2 may be electrically connected to the fourth light receiving element LRD4 to constitute a fourth light sensing pixel PSR4. That is, the second sensor circuit SC22 and the fourth light receiving element LRD4 may constitute the fourth light sensing pixel SPR4. However, embodiments according to the present disclosure are not limited thereto. According to some embodiments, only some of the sensor circuits SC11 to SC44 may be provided, and be connected to a plurality of light receiving elements.

The first sensor circuit SC11 of the first pixel row R1 may be located between the first sub-pixel unit SPU1 and the second sub-pixel unit SPU2, which are included in the pixel unit PU. For example, the first and second pixel circuits PXC11 and PXC12 of the first sub-pixel R1 may be included in the first sub-pixel unit SPU1, and the third and fourth pixel circuits PXC13 and PXC14 of the first pixel row R1 may be included in the second sub-pixel unit SPU2. At least two pixel circuits PXC13 and PXC14 may be located between the first sensor circuit SC11 and the second sensor circuit SC12, which are adjacent to each other on the first pixel row R1. However, embodiments according to the present disclosure are not limited thereto, and at least three pixel circuits or at least four pixel circuits may be located between the first sensor circuit SC11 and the second sensor circuit SC12, which are adjacent to each other, in each of the pixel rows R1 to R4.

Similarly to the first sensor circuit SC11 of the first pixel row R1, the second sensor circuit SC12 of the first pixel row R1, the first sensor circuit SC21 of the second pixel row R2, and the second sensor circuit SC22 of the second pixel row R2 may be located between the first sub-pixel unit SPU1 and the second sub-pixel unit SPU2, but embodiments according to the present disclosure are not limited thereto.

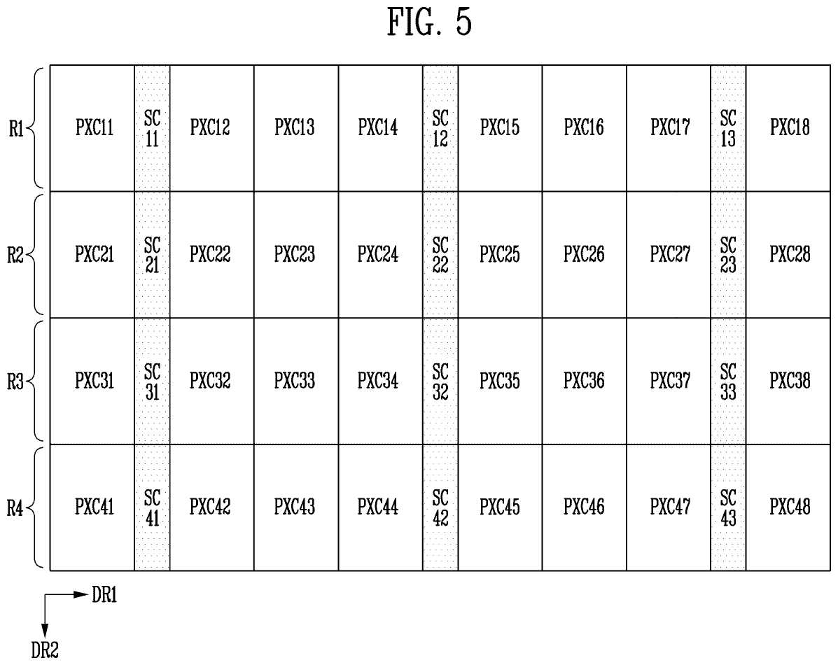

FIG. 5 is a schematic diagram illustrating an example of the arrangement of the pixel circuits and the sensor circuits of the display area of the display panel included in the display device shown in FIG. 2.

In FIG. 5, portions different from the portions of the above-described embodiments will be mainly described to avoid redundancy.

Referring to FIG. 5, the display area DA may be divided into pixel rows R1 to R4.

At least three pixel circuits may be located between two sensor circuits adjacent to each other on each of the pixel rows R1 to R4. For example, as shown in FIG. 5, a second pixel circuit PXC12, a third pixel circuit PXC13, and a fourth pixel circuit PXC14 may be located between a first sensor circuit SC11 and a second sensor circuit SC12 on a first pixel row R1. A fifth pixel circuit PXC15, a sixth pixel circuit PXC16, and a seventh pixel circuit PXC17 may be located between the second sensor circuit SC12 and a third sensor circuit SC13 on the first pixel row R1. Similarly to this, three pixel circuits may be located each of between a first sensor circuit SC21 and a second sensor circuit SC22 and between the second sensor circuit SC22 and a third sensor circuit SC23 on a second pixel row R2. Three pixel circuits may be located each of between a first sensor circuit SC31 and a second sensor circuit SC32 and between the second sensor circuit SC32 and a third sensor circuit SC33 on a third pixel row R3. Three pixel circuits may be located each of between a first sensor circuit SC41 and a second sensor circuit SC42 and between the second sensor circuit SC42 and a third sensor circuit SC43 on a fourth pixel row R4.

Sensor circuits in each of the pixel rows R1 to R4 may be located on the same column as sensor circuits adjacent in the second direction DR2. For example, the first sensor circuit SC11 of the first pixel row R1, the first sensor circuit SC21 of the second pixel row R2, the first sensor circuit SC31 of the third pixel row R3, and the first sensor circuit SC41 of the fourth pixel row R4 may be located on the same column.

FIG. 6 is a schematic circuit diagram illustrating an example of the sub-pixel and the light sensing pixel, which are included in the display area shown in FIG. 1. Although FIG. 6 illustrates various components in a sub-pixel and a light sensing pixel according to some embodiments, embodiments according to the present disclosure are not limited thereto, and according to various embodiments, the sub-pixel and the light sensing pixel may include additional components or fewer components without departing from the spirit and scope of embodiments according to the present disclosure.

In FIG. 6, for convenience of description, a sub-pixel SPX which is located on an ith horizontal line (or ith pixel row) and is connected to a jth data line Dj will be illustrated.

Referring to FIGS. 1 and 6, a sub-pixel SPX and a light sensing pixel PSR may be located on an ith horizontal line.

The sub-pixel SPX may include a light emitting element LED and a pixel circuit PXC. According to some embodiments, the pixel circuit PXC may include first, second, third, fourth, fifth, sixth, and seventh transistors T1, T2, T3, T4, T5, T6, and T7, a storage capacitor Cst, and a boost capacitor Cbst.

The first transistor T1 (or driving transistor) may be electrically connected between a first power line PL1 and a first electrode (or anode electrode) of the light emitting element LED. The first transistor T1 may include a gate electrode electrically connected to a first node N1. The first transistor T1 may control an amount of current (or driving current) flowing from the first power line PL1 to an electrode EP (or power line) via the light emitting element LED, based on a voltage of the first node N1. A first power voltage VDD may be supplied to the first power line PL1, and a second power voltage VSS may be supplied to the electrode EP. The first power voltage VDD may be set as a voltage higher than the second power voltage VSS.

The second transistor T2 may be electrically connected between a jth data line Dj and a second node N2. A gate electrode of the second transistor T2 may be connected to a 1ith scan line S1i (or first scan line). The second transistor T2 may be turned on when a first scan signal GW[i] (e.g., the first scan signal GW[i] having a low level) is supplied to the 1ith scan line S1i, to electrically connect the jth data line Dj and the second node N2 to each other. When each of the first transistor T1 and the third transistor T3 is in a turn-on state, the second transistor T2 may transfer a data signal of the jth data line Dj to the second node N2 in response to the first scan signal GW[i].

The third transistor T3 may be electrically connected between the first node N1 and a third node N3. A gate electrode of the third transistor T3 may be electrically connected to a 4ith scan line S4i (or third scan line). The third transistor T3 may be turned on when a fourth scan signal GC[i] is supplied to the 4ith scan line S4i.

The fourth transistor T4 may be electrically connected between the first node N1 and a second power line PL2. A gate electrode of the fourth transistor T4 may be electrically connected to a 2ith scan line S2i (or second scan line). A first initialization power voltage Vint1 may be supplied to the second power line PI2. The fourth transistor T4 may be turned on by a second scan signal GI[i] supplied to the 2ith scan line S2i. When the fourth transistor T4 is turned on, the first initialization power voltage Vint1 may be supplied to the first node N1 (i.e., the gate electrode of the first transistor T1).

The fifth transistor T5 may be electrically connected between the first power line PL1 and the second node N2. A gate electrode of the fifth transistor T5 may be electrically connected to an ith emission control line Ei. The sixth transistor T6 may be electrically connected between the third node N3 and the light emitting element LED (or a fourth node N4). A gate electrode of the sixth transistor T6 may be electrically connected to the ith emission control line Ei. The fifth transistor T5 and the sixth transistor T6 may be turned off when an emission control signal EM [i] (e.g., the emission control signal EM [i] having a high level) is supplied to the ith emission control line Ei, and be turned on in other cases.

The seventh transistor T7 may be electrically connected between the first electrode of the light emitting element LED (i.e., the fourth node N4) and a third power line PL3. A gate electrode of the seventh transistor T7 may be electrically connected to a 3ith scan line S3i (or fourth scan line). A second initialization power voltage Vint2 may be supplied to the third power line PL3. According to some embodiments, the second initialization power voltage Vint2 may be equal to or different from the first initialization power voltage Vint1. The seventh transistor T7 may be turned on by a third scan signal GB[i] supplied to the 3ith scan line S3i, to supply the second initialization power voltage Vint2 to the first electrode of the light emitting element LED.

The storage capacitor Cst may be connected or formed between the first power line PL1 and the first node N1.

The boost capacitor Cst (or capacitor) may be connected or formed between the gate electrode of the second transistor T2 and the gate electrode of the first transistor T1.

The light sensing pixel PSR may include a sensor circuit SC and a light receiving element LRD. The sensor circuit SC may include eighth, ninth, and tenth transistors T8, T9, and T10.

The eighth and tenth transistors T8 and T10 may be connected in series between a fifth power line PL5 and a kth readout line RXk (k is a natural number).

The eighth transistor T8 (or first sensor transistor) may be electrically connected between the fifth power line PL5 and the tenth transistor T10. A gate electrode of the eighth transistor T8 may be electrically connected to a fifth node N5 (or sensor node). The eighth transistor T8 may control a current flowing from the fifth power line PL5 to the kth readout line RXk through the tenth transistor T10 in response to a voltage of the fifth node N5. A common voltage VCOM may be supplied to the fifth power line PL5.

According to some embodiments, the fifth power line PL5 may be electrically connected to the third power line PL3 or be integrally formed with the third power line PL3, and the common voltage VCOM applied to the fifth power line PL5 may be equal to the second initialization power voltage Vint2. However, embodiments according to the present disclosure are not limited thereto. According to some embodiments, the fifth power line PL5 may be electrically connected to the second power line PL2 or be integrally formed with the second power line PL2, and the common voltage VCOM applied to the fifth power line PL5 may be equal to the first initialization power voltage Vint1.

The tenth transistor T10 (“second sensor transistor” or “switching transistor”) may be electrically connected between the eighth transistor T8 and the kth readout line RXk. A gate electrode of the tenth transistor T10 may be connected to the 1ith scan line S1i. That is, the gate electrode of the tenth transistor T10 and the gate electrode of the second transistor T2 may share the 1ith scan line S1i.

The ninth transistor T9 (or third sensor transistor) may be electrically connected between a fourth power line PL4 (or reference power line) and the fifth node N5. A gate electrode of the ninth transistor T9 may be electrically connected to a reset line RSTL. A reset voltage VRST may be supplied to the fourth power line PL4. The reset voltage VRST may be a DC voltage having a constant level. For example, the reset voltage VRST may be about −7V, but embodiments according to the present disclosure are not limited thereto.

At least one light receiving element LRD may be electrically connected between the electrode EP to which the second power voltage VSS is applied and the fifth node N5.

The light receiving element LRD may generate a charge (or current), based on incident light. That is, the light receiving element LRD may perform a function of photoelectric conversion. For example, the light receiving element LRD may be implemented as a photo diode.

When the ninth transistor T9 is turned on by a reset signal RST supplied to the reset line RSTL, the reset voltage VRST may be supplied to the fifth node N5. For example, the voltage of the fifth node N5 may be reset by the reset voltage VRST. The light receiving element LRD may perform the function of photoelectric conversion from after the reset voltage VRST is applied to the fifth node N5.

The voltage of the fifth node N5 may be changed by an operation of the light receiving element LRD. The voltage of the fifth node (or the charge or current generated by the light receiving element LRD) may be changed according to an intensity of light incident into the light receiving element LRD and a time for which the light is incident (or a time for which the light receiving element LRD is exposed to the light).

When the tenth transistor T10 is turned on by the first scan signal GW[i] supplied to the first scan line S1i, a detection value (current and/or voltage) generated based on the voltage of the fifth node N5 may flow in the kth readout line RXk.

According to some embodiments, each of the pixel circuit PXC and the sensor circuit SC may include a P-type transistor and an N-type transistor. The third transistor T3, the fourth transistor T4, and the ninth transistor T9 may be formed with an oxide semiconductor transistor including an oxide semiconductor (or second type semiconductor). For example, the third transistor T3, the fourth transistor T4, and the ninth transistor T9 may be formed with an N-type oxide semiconductor transistor, and include an oxide semiconductor layer as an active layer. However, embodiments according to the present disclosure are not limited thereto.

The other transistors (e.g., the first, second, fifth, sixth, seventh, eighth, and tenth transistors T1, T2, T5, T6, T7, T8, and T10) may be formed with a poly-silicon transistor including a silicon semiconductor (or first type semiconductor), and include a poly-silicon semiconductor layer as an active layer. For example, the active layer may be formed through a low-temperature poly-silicon (LTPS) process.

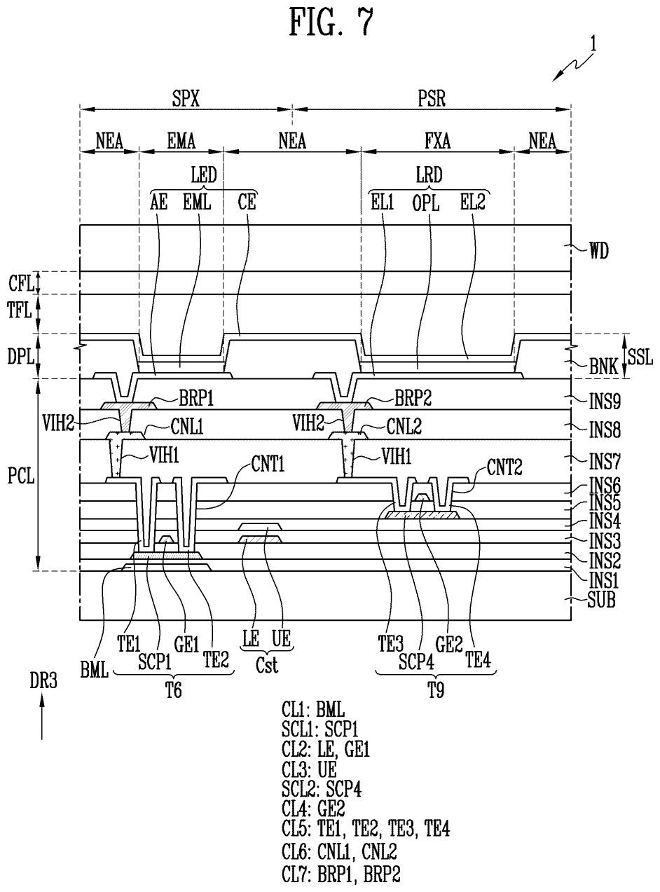

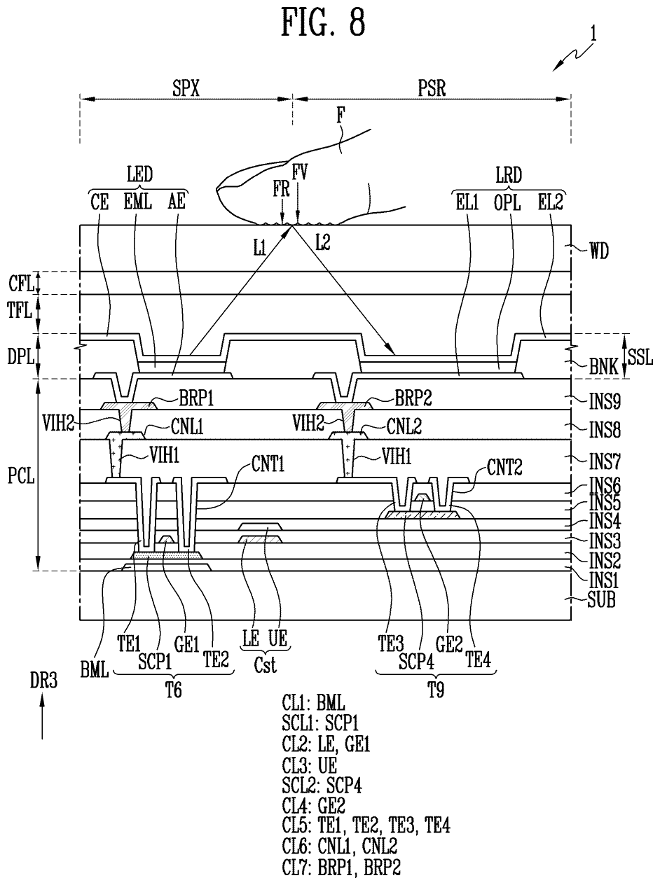

Hereinafter, a stacked structure (or sectional structure) of a sub-pixel SPX including a light emitting element LED and a light sensing pixel PSR including a light receiving element LRD will be mainly described with reference to FIGS. 7 and 8.

FIG. 7 is a schematic cross-sectional view illustrating one area of a display device 1 according to some embodiments of the present disclosure. FIG. 8 is a schematic cross-sectional view illustrating a reflection path of light in the display device 1 shown in FIG. 7.

In FIGS. 7 and 8, a section of a portion corresponding to the sixth transistor T6 in the pixel circuit PXC shown in FIG. 6 and a section of a portion corresponding to the ninth transistor T9 in the sensor circuit SC shown in FIG. 6 are illustrated.

Referring to FIGS. 1 to 8, the display device 1 may include a sub-pixel SPX and a light sensing pixel PSR, which are provided in one area of a substrate SUB.

A pixel circuit layer PCL of the sub-pixel SPX and the light sensing pixel PSR may be located on the substrate SUB. At least one insulating layer may be located in the pixel circuit layer PCL. The insulating layer may include a first insulating layer INS1, a second insulating layer INS2, a third insulating layer INS3, a fourth insulating layer INS4, a fifth insulating layer INS5, a sixth insulating layer INS6, a seventh insulating layer INS7, an eighth insulating layer INS8, and a ninth insulating layer INS9, which are sequentially stacked along a third direction DR3 on the substrate SUB.

The first insulating layer INS1 (or buffer layer) may be located on the substrate SUB. The first insulating layer INS1 may prevent or reduce diffusion of contaminants or impurities into a sixth transistor T6 and a ninth transistor T9. The first insulating layer INS1 may be an inorganic layer including an inorganic material (or substance). The first insulating layer INS1 may include at least one of silicon nitride (SiNₓ), silicon oxide (SiOₓ), silicon oxynitride (SiOₓN_{y}), or aluminum oxide (AlOₓ). The first insulating layer INS1 may be provided as a single layer, but be provided as a multi-layer including at least two layers. The first insulating layer INS1 may be omitted according to a material of the substrate SUB, a process condition, and the like.

The second insulating layer INS2 (or first gate insulating layer) may be located on the first insulating layer INS1. The second insulating layer INS2 may include the same material as the first insulating layer INS1 or include a material appropriate (or selected) from the materials described as the material constituting the first insulating layer INS1. For example, the second insulating layer INS2 may be an inorganic insulting layer including an inorganic material.

The third insulating layer INS3 (or second gate insulating layer) may be located on the second insulating layer INS2. The third insulating layer INS3 may include the same material as the first insulating layer INS1 or include a material appropriate (or selected) from the materials described as the material constituting the first insulating layer INS1.

The fourth insulating layer INS4 (or first interlayer insulating layer) may be located on the third insulating layer INS3. The fourth insulating layer INS4 may be an inorganic layer including an inorganic material or an organic layer including an organic material.

The fifth insulating layer INS5 (or third gate insulating layer) may be located on the fourth insulating layer INS4. The fifth insulating layer INS5 may be an inorganic layer including an inorganic material or an organic layer including an organic material.

The sixth insulating layer INS6 (or second interlayer insulating layer) may be located on the fifth insulating layer INS5. The sixth insulating layer INS6 may be an inorganic layer including an inorganic material or an organic layer including an organic material.

The seventh insulating layer INS7 (or first via layer) may be located on the sixth insulating layer INS6. The seventh insulating layer INS7 may be an inorganic layer including an inorganic material or an organic layer including an organic material. The inorganic layer may include, for example, at least one of silicon nitride (SiNₓ), silicon oxide (SiOₓ), silicon oxynitride (SiOₓN_{y}), or aluminum oxide (AlOₓ). The organic layer may include, for example, at least one of acrylic resin, epoxy resin, phenolic resin, polyamide resin, polyimide resin, unsaturated polyester resin, poly-phenylene ether resin, poly-phenylene sulfide resin, or benzocyclobutene resin. According to some embodiments, the seventh insulating layer INS7 may be an organic layer.

The eighth insulating layer INS8 (or second via layer) may be located on the seventh insulating layer INS7. The eighth insulating layer INS8 may include the same material as the seventh insulating layer INS7 or include a material appropriate (or selected) from the materials described as the material constituting the seventh insulating layer INS7. For example, the eighth insulating layer INS8 may be an organic layer including an organic material.

The ninth insulating layer INS9 (or third via layer) may be located on the eighth insulating layer INS8. The ninth insulating layer INS9 may include the same material as the seventh insulating layer INS7 or include a material appropriate (or selected) from the materials described as the material constituting the seventh insulating layer INS7. For example, the ninth insulating layer INS9 may be an organic layer including an organic material.

The pixel circuit layer PCL may include one or more conductive layers located between the above-described insulating layers. For example, the conductive layers may include a first conductive layer CL1 located between the substrate SUB and the first insulating layer INS1, a second conductive layer CL2 located between the second insulating layer INS2 and the third insulating layer INS3, a third conductive layer CL3 located between the third insulating layer INS3 and the fourth insulating layer INS4, a fourth conductive layer CL4 located between the fifth insulating layer INS5 and the sixth insulating layer INS6, a fifth conductive layer CL5 located between the sixth insulating layer INS6 and the seventh insulating layer INS7, a sixth conductive layer CL6 located between the seventh insulating layer INS7 and the eighth insulating layer INS8, and a seventh conductive layer CL7 located between the eighth insulating layer INS8 and the ninth insulating layer INS9. The insulating layers and the conductive layers are not limited to the above-described embodiments. According to some embodiments, another insulating layer and another conductive layer in addition to the insulating layer and the conductive layers may be located in the pixel circuit layer PCL.

According to some embodiments, a first semiconductor layer SCL1 may be located between the first insulating layer INS1 and the second insulating layer INS2. The first semiconductor layer SCL1 may include a silicon semiconductor. For example, the silicon semiconductor may include amorphous silicon, polycrystalline silicon, and the like. The first semiconductor layer SCL1 may include low temperature poly-silicon, but embodiments according to the present disclosure are not limited thereto. The first semiconductor layer SCL1 may include a first semiconductor region having a high conductivity and a second semiconductor region having a low conductivity. The first semiconductor region may be doped with an N-type dopant or a P-type dopant. A P-type transistor may include a doping region doped with a P-type dopant, and an N-type transistor may include a doping region doped with an N-type dopant. The second semiconductor region may be a non-doping region or a region doped at a low concentration as compared with the first semiconductor region. A conductivity of the first semiconductor region may be higher than a conductivity of the second semiconductor region. The first semiconductor region may substantially serve an electrode or a signal line. The second semiconductor region may substantially correspond to an active pattern (or channel region) of a transistor. A portion of the first semiconductor layer SCL1 may be an active pattern region of the transistor, another portion of the first semiconductor layer SCL1 may be a source/drain region (or source/drain electrode) of the transistor, and still another portion of the first semiconductor layer SCL1 may be a connection electrode or a connection signal line. However, embodiments according to the present disclosure are not limited thereto.

According to some embodiments, a second semiconductor layer SCL2 may be located between the fourth insulating layer INS4 and the fifth insulating layer INS5. The second semiconductor layer SCL2 may include an oxide semiconductor. The oxide semiconductor may include a plurality of regions divided according to whether a metal oxide has been reduced. A region in which the metal oxide is reduced (hereinafter, referred to as a “reduction region”) may have a high conductivity as compared with a region in which the metal oxide is not reduced (hereinafter, referred to as a “non-reduction region”). The reduction region may be substantially used as a source/drain region of a transistor or a signal line. The non-reduction region may substantially correspond to an active pattern (or channel region) of the transistor. A portion of the second semiconductor layer SCL2 may be an active pattern of the transistor, another portion of the second semiconductor layer SCL2 may be a source/drain region (or source/drain electrode) of the transistor, and still another portion of the second semiconductor layer SCL2 may be a signal transfer region. However, embodiments according to the present disclosure are not limited thereto.

The sixth transistor T6 and the ninth transistor T9 may be located in the pixel circuit layer PCL.

The sixth transistor T6 may include a gate electrode GE1 (hereinafter, referred to as a “first gate electrode”), a first semiconductor pattern SCP1, a first terminal TE1, and a second terminal TE2. The ninth transistor T9 may include a gate electrode GE2 (hereinafter, referred to as a “second gate electrode”), a fourth semiconductor pattern SCP4, a third terminal TE3, and a fourth terminal TE4.

The first semiconductor pattern SCP1 may be located on the first insulating layer INS1, and be configured with the first semiconductor layer SCL1. The first semiconductor pattern SCP1 may include a channel region (or second semiconductor region), a (1-1)th semiconductor region connected to one end of the channel region, and a (1-2)th semiconductor region connected to the other end of the channel region. The second insulating layer INS2 may be located over the first semiconductor pattern SCP1.

The first gate electrode GE1 may be located on the second insulating layer INS2, and be configured with the second conductive layer CL2. The second conductive layer CL2 may be formed as a single layer or a multi-layer, which is made of molybdenum, copper, chromium, gold, silver, titanium, nickel, neodymium, indium, tin, and/or any oxide or alloy thereof. For example, the second conductive layer CL2 may be formed as a multi-layer in which titanium, copper, and/or indium tin oxide are sequentially or repeatedly stacked, but embodiments according to the present disclosure are not limited thereto. The first gate electrode GE1 may overlap with one region of the first semiconductor pattern SCP1. The one region of the first semiconductor pattern SCP1, which overlaps with the first gate electrode GE1, may be a channel region of the sixth transistor T6. The third insulating layer INS3 may be arranged over the first gate electrode GE1.

The first terminal TE1 and the second terminal TE2 may be located on the sixth insulating layer INS6. The first terminal TE1 and the second terminal TE2 may be configured with the fifth conductive layer CL5. The fifth conductive layer CL5 may be formed as a single layer or a multi-layer, which is made of molybdenum, copper, chromium, gold, silver, titanium, nickel, neodymium, indium, tin, and/or any oxide or alloy thereof.

The first terminal TE1 may be electrically connected to the (1-2)th semiconductor region of the first semiconductor pattern SCP1 through a first contact portion CNT1 penetrating the second insulating layer INS2, the third insulating layer INS3, the fourth insulating layer INS4, the fifth insulating layer INS5, and the sixth insulating layer INS6. The first terminal TE1 may be electrically connected to an anode electrode AE of a light emitting element LED. The second terminal TE2 may be electrically connected to the (1-1)th semiconductor region of the first semiconductor pattern SCP1 through another first contact portion CNT1 penetrating the second insulating layer INS2, the third insulating layer INS3, the fourth insulating layer INS4, the fifth insulating layer INS5, and the sixth insulating layer INS6.

The seventh insulating layer INS7 may be arranged over the first terminal TE1 and the second terminal TE2.

The fourth semiconductor pattern SCP4 may be located on the fourth insulating layer INS4. The fourth semiconductor pattern SCP4 may be configured with the second semiconductor layer SCL2. The fourth semiconductor layer SCP4 may include a channel region (or non-reduction region), a first reduction region connected to one end of the channel region, and a second reduction region connected to the other end of the channel region. The fifth insulating layer INS5 may be arranged over the fourth semiconductor pattern SCP4.

The second gate electrode GE2 may be located on the fifth insulating layer INS5. The second gate electrode GE2 may be configured with the fourth conductive layer CL4. The fourth conductive layer CL4 may include the same material as the second conductive layer CL2 or the fifth conductive layer CL5 or include a material appropriate (or selected) from the materials described as the material constituting the second conductive layer CL2 or the fifth conductive layer CL5. The second gate electrode GE2 may overlap with one region of the second semiconductor pattern SCP4. The one region of the fourth semiconductor pattern SCP4, which overlaps with the second gate electrode GE2, may be a channel region of the ninth transistor T9.

The sixth insulating layer INS6 may be arranged over the second gate electrode GE2.

The third terminal TE3 and the fourth terminal TE4 may be located on the sixth insulating layer INS6. The third terminal TE3 and the fourth terminal TE4 may be configured with the fifth conductive layer CL5.

The third terminal TE3 may be electrically connected to the first reduction region of the fourth semiconductor pattern SCP4 through a second contact portion CNT2 penetrating the fifth insulating layer INS5 and the sixth insulating layer INS6. The fourth terminal TE4 may be electrically connected to the second reduction region of the fourth semiconductor pattern SCP4 through another second contact portion CNT2 penetrating the fifth insulating layer INS5 and the sixth insulating layer INS6. The third terminal TE3 and the fourth terminal TE4 may be located on the sixth insulating layer INS6 to be spaced apart from each other. The seventh insulating layer INS7 may be arranged over the third terminal TE3 and the fourth terminal TE4.

The pixel circuit layer PCL may further include a bottom metal pattern BML located on the substrate SUB. The bottom metal pattern BML may be configured with the first conductive layer CL1. The first conductive layer CL1 may include the same material as the second conductive layer CL2 or the fifth conductive layer CL5 or include a material appropriate (or selected) from the materials described as the material constituting the second conductive layer CL2 or the fifth conductive layer CL5. The bottom metal pattern BML may overlap with the sixth transistor T6. According to some embodiments, the bottom metal pattern BML may be electrically connected to the sixth transistor T6, to stabilize the channel region of the sixth transistor T6.

A storage capacitor Cst may be located in the pixel circuit layer PCL. The storage capacitor Cst may include a lower electrode LE and an upper electrode UE.

The lower electrode LE may be located on the second insulating layer INS2. The lower electrode LE may be configured with the first conductive layer CL1, and be provided in the same layer as the first gate electrode GE1. However, embodiments according to the present disclosure are not limited thereto. The third insulating layer INS3 may be arranged over the lower electrode LE.

The upper electrode UE may be located on the third insulating layer INS3. The upper electrode UE may be configured with the third conductive layer CL3, but embodiments according to the present disclosure are not limited thereto. The third conductive layer CL3 may include the same material as the second conductive layer CL2 or the fifth conductive layer CL5 or include a material appropriate (or selected) from the materials described as the material constituting the second conductive layer CL2 or the fifth conductive layer CL5. The upper electrode UE may overlap with the lower electrode LE with the third insulating layer INS3 interposed therebetween, thereby forming a capacitance.

A first connection line CNL1, a second connection line CNL2, a first bridge pattern BRP1, and a second bridge pattern BRP2 may be located in the pixel circuit layer PCL.

The first connection line CNL1 and the second connection line CNL2 may be located on the seventh insulating layer INS7. The first connection line CNL1 and the second connection line CNL2 may be configured with the sixth conductive layer CL6. The sixth conductive layer CL6 may include the same material as the second conductive layer CL2 or the fifth conductive layer CL5 or include a material appropriate (or selected) from the materials described as the material constituting the second conductive layer CL2 or the fifth conductive layer CL5. The first connection line CNL1 may be electrically connected to the first terminal TE1 of the sixth transistor T6 through a first via hole VIH1 penetrating the seventh insulating layer INS7. The second connection line CNL2 may be electrically connected to the third terminal of the ninth transistor T9 through another first via hole VIH1 penetrating the seventh insulating layer INS7. The eighth insulating layer INS8 may be arranged over the first connection line CNL1 and the second connection line CNL2.

The first bridge pattern BRP1 and the second bridge pattern BRP2 may be located on the eighth insulating layer INS8. The first bridge pattern BRP1 and the second bridge pattern BRP2 may be configured with the seventh conductive layer CL7. The seventh conductive layer CL7 may include the same material as the second conductive layer CL2 or the fifth conductive layer CL5 or include a material appropriate (or selected) from the materials described as the material constituting the second conductive layer CL2 or the fifth conductive layer CL5. The first bridge pattern BRP1 may be electrically connected to the first connection line CNL1 through a second via hole VIH2 penetrating the eighth insulating layer INS8. The second bridge pattern BRP2 may be electrically connected to the second connection line CNL2 through another second via hole VIH2 penetrating the eighth insulating layer INS8. The ninth insulating layer INS9 may be arranged over the first and second bridge patterns BRP1 and BRP2.

A display element layer DPL may be located on the pixel circuit layer PCL of the sub-pixel SPX, and a sensor element layer SSL may be located on the pixel circuit layer PCL of the light sensing pixel PSR.

The light emitting element LED and a bank BNK may be located in the display element layer DPL. The light emitting element LED may include the anode electrode AE (or pixel electrode), a light emitting layer EML, and a cathode electrode CE (or common electrode). The light emitting element LED may be electrically connected to the sixth transistor T6 through the first bridge pattern BRP1 and the first connection line CNL1. The light emitting layer EML may include a hole transport layer, an organic material layer (or light generation layer), and electron transport layer, and the like.

A light receiving element LRD and the bank BNK may be located in the sensor element layer SSL. The light receiving element LRD may be an optical type fingerprint sensor. The light receiving element LRD may sense lights reflected by ridges FR of a finger F of a user and valleys FV between the ridges FR, thereby recognizing a fingerprint of the user. For example, when the finger F of the user is in contact with a window WD on the window WD, first light L1 output from the light emitting element LED (or the light emitting layer EML) may be reflected by the ridge FR or the valley FV of the finger F, and reflected second light L2 may reach the light receiving element LRD (or a light receiving layer OPL) of the sensor element layer SSL. The light receiving element LRD may distinguish second light L2 reflected by the ridge FR of the finger F from second light L2 reflected by the valley of the finger F, thereby recognizing a pattern of the fingerprint of the user. The light receiving element LRD may be electrically connected to the ninth transistor T9. The light receiving element LRD may include a first sensor electrode EL1, the light receiving layer OPL (or photoelectric conversion layer), and a second sensor electrode EL2.

The anode electrode AE and the first sensor electrode EL1 may be located on the ninth insulating layer INS9. The anode electrode AE and the first sensor electrode EL1 may be made of a metal layer such as silver, magnesium, aluminum, platinum, palladium, gold, nickel, neodymium, iridium, chromium, or any alloy thereof, and/or indium tin oxide (ITO), indium zinc oxide (IZO), zinc oxide (ZnO), indium tin zinc oxide (ITZO), or the like. However, embodiments according to the present disclosure are not limited thereto. The anode electrode AE may be electrically connected to the first bridge pattern BRP1 through a contact hole penetrating the ninth insulating layer INS9. The first electrode EL1 may be electrically connected to the second bridge pattern BRP2 through a contact hole penetrating the ninth insulating layer INS9.

The anode electrode AE and the first sensor electrode EL1 may be simultaneously or sequentially formed through patterning using a mask.

The bank BNK may be a pixel defining layer defining (or partitioning) an emission area EMA of the sub-pixel SPX and a light receiving area FXA of the light sensing pixel PSR. The bank BNK may be an organic layer including an organic material (or substance). The organic material may include acrylic resin, epoxy resin, phenolic resin, polyamide resin, polyimide resin, and the like. The bank BNK may be located on the ninth insulating layer INS9 in a non-emission area NEA of the sub-pixel SPX and the light sensing pixel PSR.

According to some embodiments, the bank BNK may include a light absorption material or have a light absorber coated thereon, to absorb light introduced from the outside. For example, the bank BNK may include a carbon-based black pigment, but embodiments according to the present disclosure are not limited thereto. The bank BNK may include an opaque metal material, such as chromium, molybdenum, any alloy of molybdenum and titanium, tungsten, vanadium, niobium, tantalum, manganese, cobalt or nickel, which has a high absorption rate. The bank BNK may include openings corresponding to the emission area EMA and the light receiving area FXA.

The light emitting layer EML may be located on the anode electrode AE. The light emitting layer EML may include an organic light emitting layer. The light emitting layer EML may emit light such as red light, green light or blue light according to an organic material included in the light emitting layer EML.

The light receiving layer OPL may be located on the first sensor electrode EL1. The light receiving layer OPL may release electrons, corresponding to light in a specific wavelength bank, thereby sensing an intensity of the light.

The light receiving layer OPL may include a low molecular organic material (or substance). For example, the light receiving layer OPL may be made of a phthalocyanine compound including at least one metal selected from the group consisting of copper (Cu), iron (Fe), nickel (Ni), cobalt (Co), manganese (Mn), aluminum (Al), palladium (Pd), tin (Sn), indium (In), lead (Pb), titanium (Ti), rubidium (Rb), vanadium (V), gallium (Ga), terbium (Tb), cerium (Ce), lanthanum (La), and zinc (Zn).

Alternatively, the low molecular organic material included in the light receiving layer OPL may be formed as a bi-layer including a layer including a phthalocyanine compound including at least one metal selected from the group consisting of copper (Cu), iron (Fe), nickel (Ni), cobalt (Co), manganese (Mn), aluminum (Al), palladium (Pd), tin (Sn), indium (In), lead (Pb), titanium (Ti), rubidium (Rb), vanadium (V), gallium (Ga), terbium (Tb), cerium (Ce), lanthanum (La), and zinc (Zn) and a layer including C60, or be formed as a mixing layer in which the phthalocyanine compound and the C60 are mixed. However, embodiments according to the present disclosure are not limited to the above-described embodiments. According to some embodiments, the light receiving layer OPL may include a high molecular organic layer.

The cathode electrode CE may be located on the light emitting layer EML, and the second sensor electrode EL2 may be located on the light receiving layer OPL. The cathode electrode CE and the second sensor electrode EL2 may correspond to a common electrode integrally formed in the display area DA. The second power voltage (see “VSS” shown in FIG. 6) may be supplied to the cathode electrode CE and the second sensor electrode EL2.

The cathode electrode CE and the second sensor electrode EL2 may be made of a metal layer such as Ag, Mg, Al, Pt, Pd, Au, Ni, Nd, Ir or Cr, and/or a transparent conductive layer such as ITO, IZO, ZnO or ITZO. According to some embodiments, the cathode electrode CE and the second sensor electrode EL2 may be formed as a multi-layer including at least two layers including a metal thin film layer. For example, the cathode electrode CE and the second electrode EL2 may be formed a triple layer of ITO/Ag/ITO.

A thin film encapsulation layer TFE may be entirely formed over the cathode electrode CE and the second sensor electrode EL2.

The thin film encapsulation layer TFE may be formed as a single layer, but be formed as a multi-layer. The thin film encapsulation layer TFE may include a plurality of insulating layers covering the light emitting element LED and the light receiving element LRD. Specifically, the thin film encapsulation layer TFE may include at least one inorganic layer and at least one organic layer. For example, the thin film encapsulation layer TFE may have a structure in which an inorganic layer and an organic layer are alternately stacked.

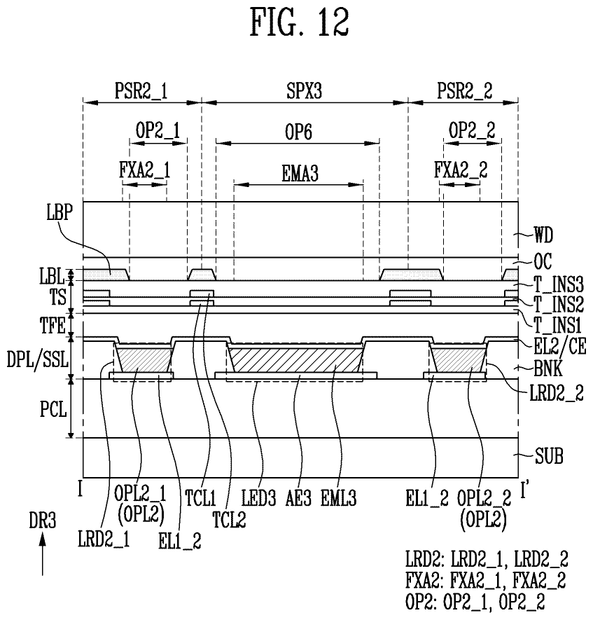

A color filter layer CFL may be located on the thin film encapsulation layer TFE. The color filter layer CFL may include a light blocking pattern and a color filter. The light blocking pattern may be located on the thin film encapsulation layer TFE to correspond to the non-emission area NEA surrounding the emission area EMA of the sub-pixel SPX and the light receiving area FXA of the light receiving pixel PSR, and the color filter may be located on the thin film encapsulation layer TFE to correspond to the emission area EMA and the light receiving area FXA. However, embodiments according to the present disclosure are not limited thereto. According to some embodiments, the color filter may be omitted such that a selective light transmitting layer including only a light blocking pattern is provided. The above-described color filter layer CFL may be used as an anti-reflection layer which blocks external light reflection. According to some embodiments, a touch sensor layer (see “TS” shown in FIG. 12) may be located between the thin film encapsulation layer TFE and the color filter layer CFL. The touch sensor layer TS will be described in detail later with reference to FIG. 12.

The window WD may be located on the color filter layer CFL.

The window WD may protect an exposed surface of the display device 1 (or the display panel (see “100” shown in FIG. 1). The window WD may protect the display device 1 from external impact, and provide an input surface and/or a display surface to the user. The window WD (or cover glass) may have a multi-layer structure selected from an organic substrate, plastic, a film, and a plastic substrate. The multi-layer structure may be formed through a continuous process or an adhesion process using an adhesive layer. The whole or a portion of the window WD may have flexibility.

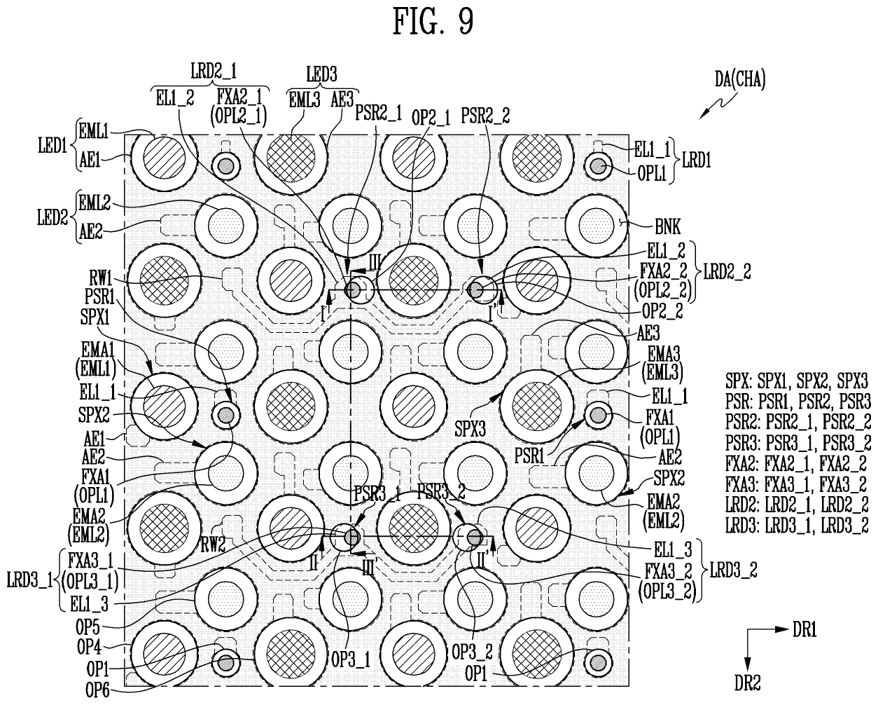

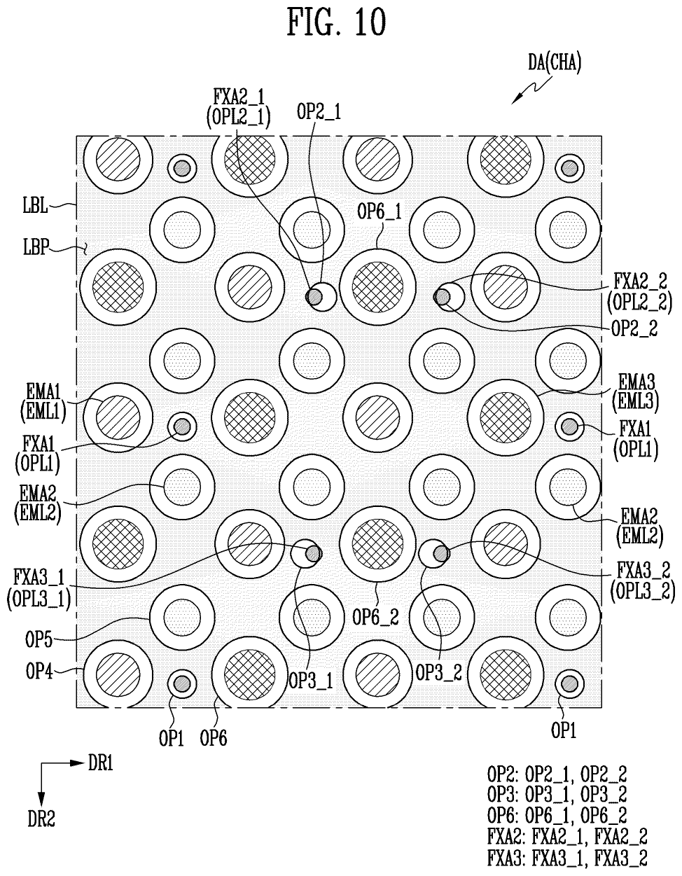

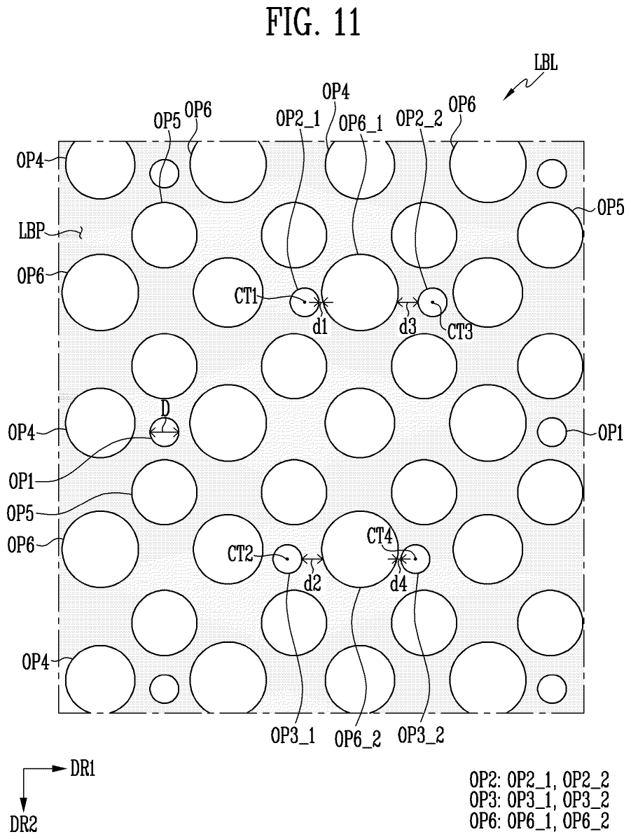

FIG. 9 is a schematic plan view illustrating one area of a display area DA of a display device according to some embodiments of the present disclosure. FIG. 10 is a schematic plan view illustrating one area of the display area DA of the display device, in which some components are omitted in FIG. 9. FIG. 11 is a schematic plan view illustrating a selective light transmitting layer LBL shown in FIG. 10.

Referring to FIGS. 9 to 11, a plurality of sub-pixels SPX and a plurality of light sensing pixels PSR may be provided in one area of the display area DA. The one area may be a capture area CHA in which a pattern of a fingerprint of a user is recognized using light incident onto the light sensing pixels PSR.

The sub-pixels SPX may include a plurality of pixel units (see “PU” shown in FIG. 4). According to some embodiments, each of the pixel units PU may include a first sub-pixel SPX1, two second sub-pixels SPX2, and a third sub-pixel SPX3. However, the number of sub-pixels SPX included in each pixel unit PU is not limited thereto. According to some embodiments, each pixel unit PU may include three sub-pixels, e.g., a first sub-pixel SPX1, one second sub-pixel SPX2, and a third sub-pixel SPX3. According to some embodiments, the first sub-pixel SPX1 may be a red pixel, the second sub-pixel SPX2 may be a green pixel, and the third sub-pixel SPX3 may be a blue pixel. However, embodiments according to the present disclosure are not limited thereto. The plurality of pixel units PU may be located in the capture area CHA.

The first sub-pixel SPX1 may include a first emission area EMA1 and a non-emission area (see “NEA” shown in FIG. 7) at the periphery of the first emission area EMA1. The second sub-pixel SPX2 may include a second emission area EMA2 and the non-emission area NEA at the periphery of the second emission area EMA2. The third sub-pixel SPX3 may include a third emission area EMA3 and the non-emission area NEA at the periphery of the third emission area EMA3. The first emission area EMA1 may be an area in which light is emitted from a first light emitting element LED1 of the first sub-pixel SPX1, the second emission area EMA2 may be an area in which light is emitted from a second light emitting element LED2 of the second sub-pixel SPX2, and the third emission area EMA3 may be an area in which light is emitted from a third light emitting element LED3 of the third sub-pixel SPX3. As described with reference to FIG. 7, each emission area may be understood as an opening of a bank BNK, which corresponds to each of the first to third sub-pixels SPX1 to SPX3.

Areas of the emission areas may be different from one another. For example, the third emission area EMA3 may be larger than each of the first emission area EMA1 and the second emission area EMA2. The shape of each emission area may be a circular shape on a plane. However, embodiments according to the present disclosure are not limited thereto, and the shape of each emission area may be variously changed, such as a quadrangular shape, an elliptical shape, and a polygonal shape.

The first sub-pixel SPX1 may include the first light emitting element LED1, the second sub-pixel SPX2 may include the second light emitting element LED2, and the third sub-pixel SPX3 may be the third light emitting element LED3. The first light emitting element LED1 may be a red light emitting element emitting red light, the second light emitting element LED2 may be a green light emitting element emitting green light, and the third light emitting element LED3 may be a blue light emitting element emitting blue light.

First light emitting elements LED1 and Third light emitting elements LED3 may be arranged to be alternately repeated in the first and second directions DR1 and DR2. Second light emitting elements LED2 may be arranged in a line form along the first direction DR1. In addition, second light emitting elements LED2 may be arranged in a line form along the second direction DR2. The second light emitting elements LED2 may be arranged on rows and columns, which are different from rows and columns, on which the first light emitting elements LED1 and the third light emitting elements LED3 are arranged. For example, the first and third light emitting elements LED1 and LED3 may be arranged on odd-numbered rows and odd-numbered columns, and the second light emitting elements LED2 may be arranged on even-numbered rows and even-numbered columns. For example, first light emitting elements LED1 and third light emitting elements LED3 may be alternately arranged while forming a first column along the second direction DR2, and second light emitting elements LED2 may be arranged to be spaced apart from each other at a distance (e.g., a set or predetermined distance) along the second direction on a second column adjacent to the first column. The arrangement of the light emitting elements may be repeated up to an nth column.

The first light emitting element LED1 may include a first anode electrode AE1 and a first light emitting layer EML1. The first light emitting element LED1 may be electrically connected to a corresponding pixel circuit (see “PXC” shown in FIG. 6). For example, the first anode electrode AE1 of the first light emitting element LED1 may be electrically connected to the corresponding pixel circuit PXC through a contact hole.

The second light emitting element LED2 may include a second anode electrode AE2 and a second light emitting layer EML2. The second light emitting element LED2 may be electrically connected to a corresponding pixel circuit PXC. For example, the second anode electrode AE2 of the second light emitting element LED2 may be electrically connected to the corresponding pixel circuit PXC through a contact hole.

The third light emitting element LED3 may include a third anode electrode AE3 and a third light emitting layer EML3. The third light emitting element LED3 may be electrically connected to a corresponding pixel circuit PXC. For example, the third anode electrode AE3 of the third light emitting element LED3 may be electrically connected to the corresponding pixel circuit PXC through a contact hole.

Each of the light sensing pixels PSR may be arranged corresponding to one pixel unit PU, but embodiments according to the present disclosure are not limited thereto. In each pixel unit PU, a first sub-pixel SPX1 (or a first light emitting element LED1) and a third sub-pixel SPX3 (or a third light emitting element LED3) may be spaced apart from each other with one light sensing pixel PSR interposed therebetween in the first direction DR1. Also, in the pixel unit PU, two second sub-pixels SPX2 (or second light emitting elements LED2) may be spaced apart from each other with the one light sensing pixel PSR interposed therebetween in the second direction DR2.

According to some embodiments, the light sensing pixels PSR may include a first light sensing pixel PSR1, a second light sensing pixel PSR2, and a third light sensing pixel PSR3.

The first light sensing pixel PSR1 may include a first light receiving area FXA1 and the non-emission area NEA at the periphery of the first light receiving area FXA1. The second light sensing pixel PSR2 may include a second light receiving area FXA2 and the non-emission area NEA at the periphery of the second light receiving area FXA2. The third light sensing pixel PSR3 may include a third light receiving area FXA3 and the non-emission area NEA at the periphery of the third light receiving area FXA3. The first light receiving area FXA1 may be an area in which light is incident onto a first light receiving element LRD1 of the first light sensing pixel PSR1, the second light receiving area FXA2 may be an area in which light is incident onto a second light receiving element LRD2 of the second light sensing pixel PSR2, and the third light receiving area FXA3 may be an area in which light is incident onto a third light receiving element LRD3 of the third light sensing pixel PSR3. As described with reference to FIG. 7, each light receiving area may be understood as an opening of the bank BNK, which corresponds to each of the first to third light sensing pixels PSR1 to PSR3. However, embodiments according to the present disclosure are not limited thereto.

First light sensing pixels PSR1 may be arranged with three sub-pixels (or three light emitting elements) interposed therebetween in the first direction DR1. For example, three sub-pixels (or three light emitting elements) may be located between two first light sensing pixels PSR1 adjacent to each other in the first direction DR1. First light sensing pixels PSR1 may be arranged with two second sub-pixels SPX2 (or two second light emitting elements LED2) interposed therebetween in the second direction DR2. For example, two second sub-pixels SPX2 (or two second light emitting elements LED2) may be located between two first light sensing pixels PSR1 adjacent to each other in the second direction DR2.

The second light sensing pixel PSR2 may include a (2-1)th light sensing pixel PSR2_1 and a (2-2)th light sensing pixel PSR2_2, which are arranged in the first direction DR1 and are electrically connected to the same sensor circuit (see “SC” shown in FIG. 6). The (2-1)th light sensing pixel PSR2_1 and the (2-2)th light sensing pixel PSR2_2 may be spaced apart from each other with one sub-pixel SPX (or one light emitting element) interposed therebetween. For example, the (2-1)th light sensing pixel PSR2_1 and the (2-2)th light sensing pixel PSR2_2 may be spaced apart from each other with one third sub-pixel SPX3 (or one third light emitting element LED3 interposed therebetween.

The third light sensing pixel PSR3 may include a (3-1)th light sensing pixel PSR3_1 and a (3-2)th light sensing pixel PSR3_2, which are arranged in the first direction and are electrically connected to the same sensor circuit SC. The (3-1)th light sensing pixel PSR3_1 and the (3-2)th light sensing pixel PSR3_2 may be spaced apart from each other with one sub-pixel SPX (or one light emitting element) interposed therebetween. For example, the (3-1)th light sensing pixel PSR3_1 and the (3-2)th light sensing pixel PSR3_2 may be spaced apart from each other with one third sub-pixel SPX3 (or one third light emitting element LED3).

According to some embodiments, the second light sensing pixel PSR2 and the third light sensing pixel PSR3 may be located on the same column in the second direction DR2. For example, the (2-1)th light sensing pixel PSR2_1 and the (3-1)th light sensing pixel PSR3_1 may be located on the same column in the second direction DR2, and the (2-2)th light sensing pixel PSR2_2 and the (3-2)th light sensing pixel PSR3_2 may be located on the same column in the second direction DR2. In a plan view, the second light sensing pixel PSR2 may be located upwardly of the third light sensing pixel PSR3 in the capture area CHA.

The first light sensing pixel PSR1 may include a first light receiving element LRD1, the second light sensing pixel PSR2 may include a second light receiving element LRD2, and the third light sensing pixel PSR3 may include a third light emitting element LRD3. The second light receiving element LRD2 may include a (2-1)th sub-light receiving element LRD2_1 and a (2-2)th sub-light receiving element LRD2_2. The third light receiving element LRD3 may include a (3-1)th sub-light receiving element LRD3_1 and a (3-2)th sub-light receiving element LRD3_2.

The first light receiving element LRD1 may include a (1-1)th sensor electrode EL1_1 and a first light receiving layer OPL1 (or first photoelectric conversion layer). The first light receiving element LRD1 may be electrically connected to a corresponding sensor circuit SC. For example, the (1-1)th sensor electrode EL1_1 of the first light receiving element LRD1 may be electrically connected to the corresponding sensor circuit SC through a contact hole. The (1-1)th sensor electrode EL1_1 may be the first sensor electrode EL1 described with reference to FIG. 7. An area in which the first light receiving layer OPL1 is located may correspond to the first light receiving area FXA1 of the first light sensing pixel PSR1.

The (2-1)th sub-light receiving element LRD2_1 (or first sub-light receiving element) may include a (1-2)th sensor electrode EL1_2 and a (2-1)th light receiving layer OPL2_1 (or (2-1)th photoelectric conversion layer). The (2-1)th sub-light receiving element LRD2_1 may be electrically connected to a corresponding sensor circuit SC. For example, the (1-2)th sensor electrode EL1_2 of the (2-1)th sub-light receiving element LRD2_1 may be electrically connected to the corresponding sensor circuit SC through a contact hole. An area in which the (2-1)th light receiving layer OPL2_1 is located may corresponding to the (2-1)th light receiving area FXA2_1 of the (2-1)th light sensing pixel PSR2_1.

The (2-2)th sub-light receiving element LRD2_2 (or second sub-light receiving element) may include a (1-2)th sensor electrode EL1_2 and a (2-2)th light receiving layer OPL2_2 (or (2-2)th photoelectric conversion layer). The (2-2)th sub-light receiving element LRD2_2 may be electrically connected to a corresponding sensor circuit SC. For example, the (1-2)th sensor electrode EL1_2 of the (2-2)th sub-light receiving element LRD2_2 may be electrically connected to the corresponding sensor circuit SC through a contact hole. An area in which the (2-2)th sub-light receiving element LRD2_2 is located may correspond to a (2-2)th light receiving are FXA2_2 of the (2-2)th light sensing pixel PSR2_2.

According to some embodiments, the (2-1)th sub-light receiving element LRD2_1 and the (2-2)th sub-light receiving element LRD2_2 may be electrically connected to each other through a first routing line RW1. For example, the first routing line RW1 extending in the first direction DR1 may be electrically connected to the (1-2)th sensor electrode EL1_2 of the (2-1)th sub-light receiving element LRD2_1 and the (1-2)th sensor electrode EL1_2 of the (2-2)th sub-light receiving element LRD2_2. The first routing line RW1 may be integrally formed with the (1-2)th sensor electrode EL1_2 of the (2-1)th sub-light receiving element LRD2_1 and the (1-2)th sensor electrode EL1_2 of the (2-2)th sub-light receiving element LRD2_2. The (2-1)th and (2-2)th sub-light receiving elements LRD2_1 and LRD2_2 may be connected in parallel to the same sensor circuit SC by the first routing line RW1. Therefore, the (2-1)th and (2-2)th sub-light receiving elements LRD2_1 and LRD2_2 may be simultaneously turned on or be simultaneously turned off by the same sensor circuit SC.

The first routing line RW1, the (1-2)th sensor electrode EL1_2 of the (2-1)th sub-light receiving element LRD2_1, and the (1-2)th sensor electrode EL1_2 of the (2-2)th sub-light receiving element LRD2_2 may be located on the same layer as the first to third anode electrodes AE1, AE2, and AE3. The first routing line RW1, the (1-2)th sensor electrode EL1_2 of the (2-1)th sub-light receiving element LRD2_1, the (1-2)th sensor electrode EL1_2 of the (2-2)th sub-light receiving element LRD2_2, and the first to third anode electrodes AE1, AE2, and AE3 may include the same material, and be provided through the same process.

The (3-1)th sub-light receiving element LRD3_1 (or third sub-light receiving element) may include a (1-3)th sensor electrode EL1_3 and a (3-1)th light receiving layer OPL2_2 (or (3-1)th photoelectric conversion layer). The (3-1)th sub-light receiving element LRD2_2 may be electrically connected to a corresponding sensor circuit SC. For example, the (1-3)th sensor electrode EL1_2 of the (3-1)th sub-light receiving element LRD3_1 may be electrically connected to the corresponding sensor circuit SC through a contact hole. An area in which the (3-1)th sub-light receiving element LRD3_1 is located may correspond to a (3-1)th light receiving are FXA3_1 of the (3-1)th light sensing pixel PSR3_1.

The (3-2)th sub-light receiving element LRD3_2 (or fourth sub-light receiving element) may include a (1-3)th sensor electrode EL1_3 and a (3-2)th light receiving layer OPL3_2 (or (3-2)th photoelectric conversion layer). The (3-2)th sub-light receiving element LRD3_2 may be electrically connected to a corresponding sensor circuit SC. For example, the (1-3)th sensor electrode EL1_3 of the (3-2)th sub-light receiving element LRD3_2 may be electrically connected to the corresponding sensor circuit SC through a contact hole. An area in which the (3-2)th sub-light receiving element LRD3_2 is located may correspond to a (3-2)th light receiving are FXA3_2 of the (3-2)th light sensing pixel PSR3_2.

According to some embodiments, the (3-1)th sub-light receiving element LRD3_1 and the (3-2)th sub-light receiving element LRD3_2 may be electrically connected to each other through a second routing line RW2. For example, the first routing line RW1 extending in the first direction DR1 may be electrically connected to the (1-3)th sensor electrode EL1_3 of the (3-1)th sub-light receiving element LRD3_1 and the (1-3)th sensor electrode EL1_3 of the (3-2)th sub-light receiving element LRD3_2. The second routing line RW2 may be integrally formed with the (1-3)th sensor electrode EL1_3 of the (3-1)th sub-light receiving element LRD3_1 and the (1-3)th sensor electrode EL1_3 of the (3-2)th sub-light receiving element LRD3_2. The (3-1)th and (3-2)th sub-light receiving elements LRD3_1 and LRD3_2 may be connected in parallel to the same sensor circuit SC by the second routing line RW2. Therefore, the (3-1)th and (3-2)th sub-light receiving elements LRD3_1 and LRD3_2 may be simultaneously turned on or be simultaneously turned off by the same sensor circuit SC.

The second routing line RW2, the (1-3)th sensor electrode EL1_3 of the (3-1)th sub-light receiving element LRD3_1, and the (1-3)th sensor electrode EL1_3 of the (3-2)th sub-light receiving element LRD3_2 may be located on the same layer as the first to third anode electrodes AE1, AE2, and AE3. The second routing line RW2, the (1-3)th sensor electrode EL1_3 of the (3-1)th sub-light receiving element LRD3_1, the (1-3)th sensor electrode EL1_3 of the (3-2)th sub-light receiving element LRD3_2, and the first to third anode electrodes AE1, AE2, and AE3 may include the same material, and be provided through the same process.

A selective light transmitting layer LBL including openings overlapping with light emitting elements and light receiving elements may be located on the light emitting elements and the light receiving elements. According to some embodiments, the selective light transmitting layer LBL may allow light (hereinafter, referred to as “reflected light”) reflected from an object, e.g., a fingerprint of a finger of a user, which is located on a display surface of the display device (see “1” shown in FIG. 1), to be selectively transmitted through the light receiving elements, thereby controlling a path of the reflected light, or the like.

The selective light transmitting layer LBL may be located between an element layer (e.g., a display element layer DPL and a sensor element layer SSL) and a window (see “WD” shown in FIG. 12), and include a plurality of openings and a light blocking pattern LBP.

The light blocking pattern LBP may include a light blocking material. For example, the light blocking pattern LBP may include a black matrix, but embodiments according to the present disclosure are not limited thereto. According to some embodiments, the light blocking pattern LBP may include at least one of carbon black (CB) or titan black (TiBK). Each of the openings may be an empty spaced opened by removing at least one area of the light blocking pattern LBP. Each of the openings may be a penetration hole penetrating at least one area of the light blocking pattern LBP.

The openings may include a first opening OP1, a second opening OP2, a third opening OP3, a fourth opening OP4, a fifth opening OP5, and a sixth opening OP6. The first to sixth openings OP1 to OP6 may have a circular shape.

The first opening OP1 (or first light blocking opening) may overlap with the first light receiving element LRD1 (or the first light sensing pixel PSR1, the second opening OP2 (or second light blocking opening) overlap with the second light receiving element LRD2 (or the second light sensing pixel PSR2), the third opening OP3 (or third light blocking opening) may overlap with the third light receiving element LRD3 (or the third light sensing pixel PSR3), the fourth opening OP4 (or first light emitting opening) may overlap with the first light emitting element LED1 (or the first sub-pixel SPX1), the fifth opening OP5 (or second light emitting opening) may overlap with the second light emitting element LED2 (or the second sub-pixel SPX2), and the sixth opening OP6 (or third light emitting opening) may overlap with the third light emitting element LED3 (or the third sub-pixel SPX3).

According to some embodiments, the second opening OP2 may include a (2-1)th opening OP2_1 overlapping with the (2-1)th sub-light receiving element LRD2_1 and a (2-2)th opening OP2_2 overlapping with the (2-2)th sub-light receiving element LRD2_2. The third opening OP3 may include a (3-1)th opening OP3_1 overlapping with the (3-1)th sub-light receiving element LRD3_1 and a (3-2)th opening OP3_2 overlapping with the (3-2)th sub-light receiving element LRD3_2.

One sixth opening OP6 may be located between the (2-1)th opening OP2_1 and the (2-2)th opening OP2_2 in the first direction DR1, and another sixth opening OP6 may be located between the (3-1)th opening OP3_1 and the (3-2)th opening OP3_2 in the first direction DR1. For convenience of description, the one sixth opening OP6 located between the (2-1)th opening OP2_1 and the (2-2)th opening OP2_2 may be referred to as a (6-1)th opening OP6_1, and the another sixth opening OP6 located between the (3-1)th opening OP3_1 and the (3-2)th opening OP3_2 may be referred to as a (6-2)th opening OP6_2.

In a plan view, fourth openings OP4 and sixth openings OP6 may be arranged to be alternately repeated in the first and second directions DR1 and DR2. In a plan view, fifth openings OP5 may be arranged in a line form along each of the first and second directions DR1 and DR2. A size of the sixth opening OP6 may be greater than a size of each of the other openings (e.g., the first to fifth openings OP1 to OP5).

According to some embodiments, the first opening OP1, the second opening OP2, and the third opening OP3 may have the same size. A diameter D of each of the first to third openings OP1 to OP3 may be about 10 μm, but embodiments according to the present disclosure are not limited thereto.

In a plan view, first openings OP1 may be arranged with three light openings interposed therebetween in the first direction DR1. For example, three light emitting openings may be located between two first openings OP1 adjacent to each other in the first direction DR1. In addition, first openings OP1 may be arranged with two fifth openings OP5 (or two second light emitting openings) interposed therebetween in the second direction DR2. For example, two fifth openings OP5 may be located between two first openings OP1 adjacent to each other in the second direction DR2. In a plan view, the first opening OP1 may surround an edge of the first light receiving layer OPL1 of the first light receiving element LRD1 (or the first light receiving area FXA1). The first light receiving element OPL1 may not overlap with the light blocking pattern LBP.

In a plan view, a first shortest distance d1 between the (2-1)th opening OP2_1 and the (6-1)th opening OP6_1 may be smaller than a third shortest distance d3 between the (2-2)th opening OP2_2 and the (6-1)th opening OP6_1. For example, the (2-1)th opening OP2_1 may be located in the light blocking pattern LBP to be biased toward the (6-1)th opening OP6_1 in the first direction DR1, and the (2-2)th opening OP2_2 may be located in the light blocking pattern LBP to be distant from the (6-1)th opening OP6_1 (or to be biased toward another sixth opening OP6 adjacent to the (6-1)th opening OP6_1) in the first direction DR1. That is, the (2-1)th opening OP2_1 may be located more adjacent to the (6-1)th opening OP6_1 than the (2-2)th opening OP2_2.

In a plan view, a second shortest distance d2 between the (3-1)th opening OP3_1 and the (6-2)th opening OP6_2 may be greater than a fourth shortest distance d4 between the (3-2)th opening OP3_2 and the (6-2)th opening OP6_2. For example, the (3-1)th opening OP3_1 may be located in the light blocking pattern LBP to be distant from the (6-2)th opening OP6_2 (or to be biased toward another sixth opening OP6 adjacent to the (6-2)th opening OP6_2) in the first direction DR1, and the (3-2)th opening OP3_2 may be located in the light blocking pattern LBP to be biased toward the (6-2)th opening OP6_2. That is, the (3-2)th opening OP3_2 may be located more adjacent to the (6-2)th opening OP6_2 than the (3-1)th opening OP3_1.

According to some embodiments, the first shortest distance d1 and the fourth shortest distance d4 may be the same, and the second shortest distance d2 and the third shortest distance d3 may be the same. However, embodiments according to the present disclosure are not limited thereto.

In a plan view, the (2-1)th opening OP2_1 and the (3-1)th opening OP3_1 may be located on different columns in the second direction DR2. In other words, a center CT1 of the (2-1)th opening OP2_1 and a center CT2 of the (3-1)th opening OP3_1 may not be located on the same column in the second direction DR2. For example, one edge of the (2-1)th opening OP2_1 may be located rightwardly (or inwardly) of one edge of the (3-1)th opening OP3_1 in the first direction DR1 on a plane.

In a plan view, the (2-2)th opening OP2_2 and the (3-2)th opening OP3_2 may be located on different columns in the second direction DR2. In other words, a center CT3 of the (2-2)th opening OP2_2 and a center CT4 of the (3-2)th opening OP3_2 may not be located on the same column in the second direction DR2. For example, one edge of the (2-2)th opening OP2_2 may be located rightwardly (or inwardly) of one edge of the (3-2)th opening OP3_2 in the first direction DR1 on a plane.

According to some embodiments, a center of the second opening OP2 and a center of the third opening OP3 may be shifted in directions opposite to each other along the first direction DR1. For example, the center CT1 of the (2-1)th opening OP2_1 and the center CT2 of the (3-1)th opening OP3_1 may be shifted in directions opposite to each other along the first direction DR1. The center CT3 of the (2-2)th opening OP2_2 and the center CT4 of the (3-2)th opening OP3_2 may be shifted in directions opposite to each other along the first direction DR1. The center CT1 of the (2-1)th opening OP2_1 may be shifted in the first direction DR1, and the center CT2 of the (3-1)th opening OP3_1 may be shifted in the opposite direction of the first direction DR1. The center CT3 of the (2-2)th opening OP2_2 may be shifted in the first direction DR1, and the center CT4 of the (3-2)th opening OP3_2 may be shifted in the opposite direction of the first direction DR1. For example, the centers of the (2-1)th and (2-2)th openings OP2_1 and OP2_3 may be shifted to a right side, and the centers of the (3-1)th and (3-2)th openings OP3_1 and OP3_2 may be shifted to a left side.

As described above, when the center CT1 of the (2-1)th opening OP2_1 is shifted to the right side, at least a portion of the (2-1)th light receiving layer OPL2_1 of the (2-1)th sub-light receiving element LRD2_1 may overlap with the light blocking pattern LBP. When the center CT3 of the (2-2)th opening OP2_2 is shifted to the right side, at least a portion of the (2-2)th light receiving layer OPL2_2 of the (2-2)th sub-light receiving element LRD2_2 may overlap with the light blocking pattern LBP. In addition, when the center CT2 of the (3-1)th opening OP3_1 is shifted to the left side, at least a portion of the (3-1)th light receiving layer OPL3_1 of the (3-1)th sub-light receiving element LRD3_1 may overlap with the light blocking pattern LBP. When the center CT4 of the (3-2)th opening OP3_2 is shifted to the left side, at least a portion of (3-2)th light receiving layer OPL3_2 of the (3-2)th sub-light receiving element LRD3_2 may overlap with the light blocking pattern LBP.

As at least a portion of each of the (2-1)th and (2-2)th light receiving layers OPL2_1 and OPL2_2 overlaps with the light blocking pattern LBP, an amount of light incident onto the (2-1)th and (2-2)th light receiving layers OPL2_1 and OPL2_2 through a corresponding opening OP2 may be decreased. The amount of light incident onto the (2-1)th and (2-2)th light receiving layers OPL2_1 and OPL2_2 may be substantially similar or equal to an amount of light incident onto the first light receiving layer OPL1 of the first light receiving element LRD1. As at least a portion of each of the (3-1)th and (3-2)th light receiving layers OPL3_1 and OPL3_2 overlaps with the light blocking pattern LBP, an amount of light incident onto the (3-1)th and (3-2)th light receiving layers OPL3_1 and OPL3_2 through a corresponding third opening OP3 may be decreased. The amount of light incident onto the (3-1)th and (3-2)th light receiving layers OPL3_1 and OPL3_2 may be substantially similar or equal to an amount of light incident onto the first light receiving layer OPL1 of the first light receiving element LRD1.

According to some embodiments, as one third light emitting element LED3 is located between the (2-1)th sub-light receiving element LRD2_1 and the (2-2)th sub-light receiving element LRD2_2, a separation distance between the (2-1)th sub-light receiving element LRD2_1 and the (2-2)th sub-light receiving element LRD2_2 may be narrower than a separation distance between two first light receiving elements LRD1 adjacent to each other. In addition, as one third light emitting element LED3 is located between the (3-1)th sub-light receiving element LRD3_1 and the (3_2)th sub-light receiving element LRD3_2, a separation distance between the (3-1)th sub-light receiving element LRD3_1 and the (3_2)th sub-light receiving element LRD3_2 may be narrower than a separation distance between two first light receiving elements LRD1 adjacent to each other. A large amount of light may be incident onto the second light receiving element LRD2 including the (2-1)th and (2-2)th sub-light receiving elements LRD2_1 and LRD2_2, as compared with the first light receiving element LRD1. Similarly, a large amount of light may be incident onto the third light receiving element LRD3 including the (3-1)th and (3-2)th sub-light receiving elements LRD3_1 and LRD3_2, as compared with the first light receiving element LRD1. Accordingly, a variation in amount of light incident onto each light receiving element occurs, and therefore, the fingerprint sensitivity and fingerprint sensing accuracy in each light sensing pixel PSR may be deteriorated.

Accordingly, in the above-described embodiments, as the (2-1)th and (2-2)th openings OP2_1 and OP2_2 and the (3-1)th and (3-2)th openings OP3_1 and OP3_2 are shifted in directions opposite to each other, the light blocking pattern LBP may overlap with at least a portion of each of corresponding (2-1)th and (2-2)th light receiving layers OPL2_1 and OPL2_2 and corresponding (3-1)th and (3-2)th light receiving layers OPL3_1 and OPL3_2. The amount of light incident onto the (2-1)th light receiving layer OPL2_1 overlapping with the (2-1)th opening OP2_1, the (2-2)th light receiving layer OPL2_2 overlapping with the (2-2)th opening OP2_2, the (3-1)th light receiving layer OPL3_1 overlapping the (3-1)th opening OP3_1, and the (3-2)th light receiving layer OPL32 overlapping with the (3-2)th opening OP3_2 may be decreased. An amount of light incident onto a light receiving layer overlapping with the second and third openings OP2 and OP2 may be substantially similar or equal to an amount of light incident onto the first light receiving layer OPL1 overlapping with the first opening OP1. Accordingly, amounts of light incident onto light receiving elements becomes similar or equal to one another, so that a failure according to a variation in light receiving amount can be reduced or prevented, thereby relatively improving the reliability of the display device 1.

Further, according to some embodiments, a second opening OP2 and a third opening OP3 are located in the light blocking pattern LBP to be shifted in directions opposite to each other, so that an overlay between a second light receiving element LRD2 overlapping with the second opening OP2 and the light blocking pattern LBP and an overlay between a third light receiving element LRD3 overlapping with the third opening OP3 and the light blocking pattern LBP can become similar to each other, thereby preventing or reducing instances of a failure according to an overlay variation.

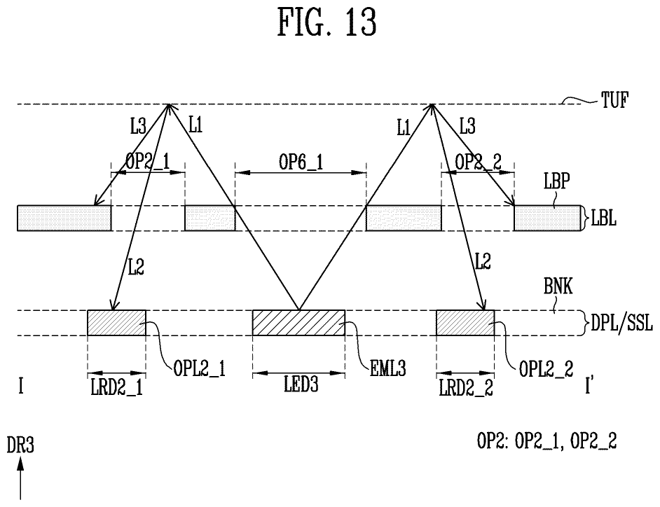

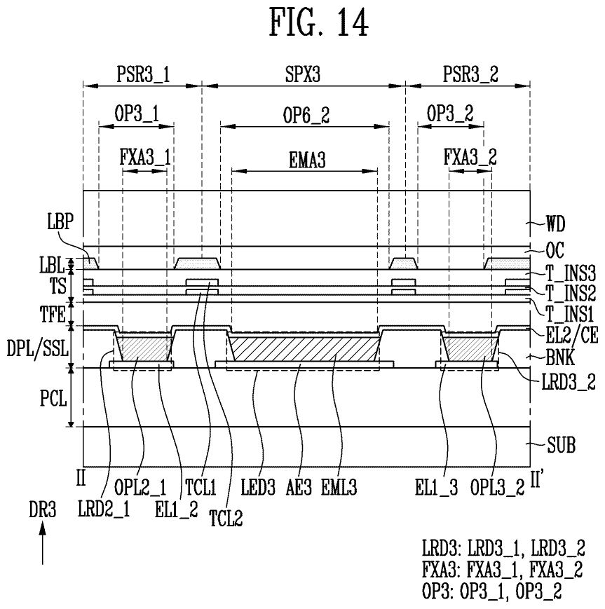

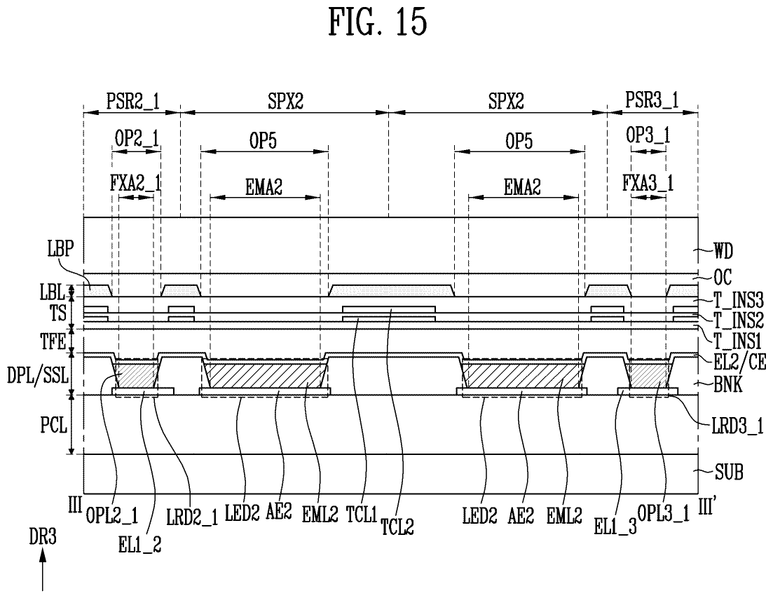

FIG. 12 is a schematic cross-sectional view taken along line I-I′ shown in FIG. 9. FIG. 13 is a schematic cross-sectional view illustrating only some components in FIG. 12. FIG. 14 is a schematic cross-sectional view taken along line II-II′ shown in FIG. 9. FIG. 15 is a schematic cross-sectional view taken along line III-III′ shown in FIG. 9.

In FIGS. 12 to 15, portions different from the portions of the above-described embodiments will be mainly described to avoid redundancy.

Referring to FIGS. 9 and 12 to 15, a display panel (see “100” shown in FIG. 1) may include a substrate SUB, a pixel circuit layer PCL, an element layer, a thin film encapsulation layer TFE, a touch sensor layer TS, a selective light transmitting layer LBL, an overcoat layer OC, and a window WD.

The substrate SUB may include a transparent insulating material to allow light to be transmitted therethrough. The substrate SUB may be a rigid substrate or a flexible substrate.

A pixel circuit (see “PXC” shown in FIG. 6) of each of first to third sub-pixels SPX1 to SPX3, a sensor circuit (see “SC” shown in FIG. 6) of each of first to third light sensing pixels PSR1 to PSR3, and signal lines may be located in the pixel circuit layer PCL.

The element layer may include a display element layer DPL and a sensor element layer SSL. A bank BNK, a first light emitting element LED1, a second light emitting element LED2, and a third light emitting element LED3 may be located in the display element layer DPL. In addition, the bank BNK, a first light receiving element LRD1, a second light receiving element LRD2, and a third light receiving element LRD3 may be located in the sensor element layer SSL.

First to third anode electrodes AE1 to AE3 may be located on the pixel circuit layer PCL, and (1-1)th to (1-3)th sensor electrodes EL1_1 to EL1_3 may be located on the pixel circuit layer PCL. The first to third anode electrodes AE1 to AE3 and the (1-1)th to (1-3)th sensor electrodes EL1_1 to EL1_3 may be arranged to be spaced apart from each other.

The first anode electrode AE1, the second anode electrode AE2, and the third anode electrode AE3 may be located on the pixel circuit layer PCL to be spaced apart from each other. The (1-1)th sensor electrode EL1_1, the (1-2)th sensor electrode EL1_2, and the (1-3)th sensor electrode EL1_3 may be located on the pixel circuit layer PCL to be spaced apart from each other.

The first to third anode electrodes AE1 to AE3 may have a shape similar to the shape of the first to third emission areas EMA1 to EMA3 shown in FIG. 9 when viewed in the third direction DR3, but embodiments according to the present disclosure are not limited thereto. The first to third anode electrodes AE1 to AE3 may have the same thickness. The (1-1)th to (1-3)th sensor electrodes EL1_1 to EL1_3 may have a shape similar to the shape of the first to third light receiving areas FXA1 to FXA3 shown in FIG. 9 when viewed in the third direction DR3, but embodiments according to the present disclosure are not limited thereto. The (1-1)th to (1-3)th sensor electrodes EL1_1 to EL1_3 may have the same thickness.

The bank BNK may be located on portions of the first to third anode electrodes AE1 to AE3, portions of the (1-1)th to (1-3)th sensor electrodes EL1_1 to EL1_3, and the pixel circuit layer PCL. The bank BNK may expose a portion of each of the first to third anode electrodes AE1 to AE3 and the (1-1)th to (1-3)th sensor electrodes EL1_1 to EL1_3.

A corresponding light emitting layer may be located on an anode electrode exposed to an outside. For example, a first light emitting layer EML1 may be located on the first anode electrode AE1, a second light emitting layer EML2 may be located on the second anode electrode AE2, and a third light emitting layer EML3 may be located on the third anode electrode AE3. The first to third light emitting elements EML1 to EML3 may be surrounded by the bank BNK.

A corresponding light receiving layer may be located on a sensor electrode exposed to an outside. For example, a first light receiving layer OPL1 may be located on the (1-1)th sensor electrode EL1_1, a second light receiving layer OPL2 may be located on the (1-2)th sensor electrode EL1_2, and a third light receiving layer OPL3 may be located on the (1-3)th sensor electrode EL1_3.

A cathode electrode CE may be located on the first to third light emitting layers EML1 to EML3 and the bank BNK, and a second sensor electrode EL2 may be located on the first to third light receiving layers OPL1 to OPL3 and the bank BNK.

The first anode electrode AE1, a portion of the first light emitting layer EML1, which overlaps with the first anode electrode AE1, and the cathode electrode CE overlapping with the first node electrode AE1 may constitute the first light emitting element LED1. The second anode electrode AE2, a portion of the second light emitting layer EML2, which overlaps with the second anode electrode AE2, and the cathode electrode CE overlapping with the second node electrode AE2 may constitute the second light emitting element LED2. The third anode electrode AE3, a portion of the third light emitting layer EML3, which overlaps with the third anode electrode AE3, and the cathode electrode CE overlapping with the third node electrode AE3 may constitute the third light emitting element LED3.

The (1-1)th sensor electrode EL1_1, a portion of the first light receiving layer OPL1, which overlaps with the (1-1)th sensor electrode EL1_1, and the second sensor electrode EL2 overlapping with the (1-1)th sensor electrode EL1_1 may constitute the first light receiving element LRD1. The (1-2)th sensor electrode EL1_2, a portion of the second light receiving layer OPL2, which overlaps with the (1-2)th sensor electrode EL1_2, and the second sensor electrode EL2 overlapping with the (1-2)th sensor electrode EL1_2 may constitute the second light receiving element LRD2. The (1-3)th sensor electrode EL1_3, a portion of the third light receiving layer OPL3, which overlaps with the (1-3)th sensor electrode EL1_3, and the second sensor electrode EL2 overlapping with the (1-3)th sensor electrode EL1_3 may constitute the third light receiving element LRD3.

The thin film encapsulation layer TFE may be arranged over the cathode electrode CE and the second sensor electrode EL2.

The touch sensor layer TS may be located on the thin film encapsulation layer TFE. The thin film encapsulation layer TFE may have a thickness of about 6.2 μm in the third direction DR3, but embodiments according to the present disclosure are not limited thereto.

The touch sensor layer TS may include a first touch insulating layer T_INS1, a second touch insulating layer T_INS2, a third touch insulating layer T_INS3, and first and second touch conductive layers TCL1 and TCL2. Each of the above-described layers may be formed as a single layer, but embodiments according to the present disclosure are not limited thereto. According to some embodiments, each of the above-described layers may be formed as a stacked layer including a plurality of layers. Another layer may be further located between the above-described layers.

The first touch insulating layer T_INS1 may include an inorganic insulating layer including an inorganic material or an organic insulating layer including an organic material. The inorganic insulating layer may include an inorganic insulating material such as silicon oxide (SiOₓ), silicon nitride (SiNₓ), silicon oxynitride (SiOₓN_{y}), aluminum oxide (AlₓO_{y}), titanium oxide (TiOₓ), tantalum oxide (TaₓO_{y}), hafnium oxide (HfOₓ), or zinc oxide (ZnOₓ). The organic insulating layer may include at least one of acrylic resin, methacrylate resin, polyisoprene resin, vinyl resin, epoxy resin, urethane resin, cellulose resin, siloxane resin, polyamide resin, or perylene resin.

The first touch insulating layer T_INS1 may be omitted in some embodiments, or be configured as an uppermost layer of the thin film encapsulation layer TFE.

The first touch conductive layer TCL1 may be provided and/or formed on the first touch insulating layer T_INS1. The first touch conductive layer TCL1 may have a single-layer structure or have a multi-layer structure in which layers are stacked in a thickness direction (e.g., third direction DR3). A touch conductive layer having a single-layer structure may include a metal layer and a transparent conductive layer. The metal layer may include molybdenum, silver, titanium, copper, aluminum, and alloys thereof. The transparent conductive layer may include a transparent conductive oxide such as indium tin oxide (ITO), indium zinc oxide (IZO), zinc oxide (ZnOₓ), or indium tin zinc oxide (ITZO). In addition, the transparent conductive layer may include PEDOT, metal nano wire, and graphene. The touch conductive layer TCL1 may constitute a first layer of a plurality of touch electrodes.

In order to prevent or reduce instances of an opening ratio of each of sub-pixels (see “SPX” shown in FIG. 9) and light sensing pixels (see “PSR” shown in FIG. 9) being lowered, the first touch conductive layer TCL1 may be located on one surface of the first touch insulating layer T_INS1 to overlap with the bank BNK. That is, the first touch conductive layer TCL1 may be located on the one surface of the first touch insulating layer T_INS1 while avoiding emission areas of the sub-pixels SPX and light receiving areas of the light sensing pixels PSR so as to ensure image quality and light receiving amount.

The second touch insulating layer T_INS2 may be entirely provided and/or formed over the first touch conductive layer TCL1 and the first touch insulating layer T_INS1. The second touch insulating layer T_INS2 may electrically insulate the first touch conductive layer TCL1 and the second touch conductive layer TCL2 from each other while being located between the first touch conductive layer TCL1 and the second touch conductive layer TCL2. The second touch insulating layer T_INS2 may include the same material as the above-described first touch insulating layer T_INS1 or include at least one material selected from the materials described as the material constituting the first touch insulating layer T_INS1. For example, the second touch insulating layer T_INS2 may include an inorganic layer, but embodiments according to the present disclosure are not limited thereto. According to some embodiments, the second touch insulating layer T_INS2 may be partially opened to include a contact hole exposing one area of the first touch conductive layer TCL1.

The second touch conductive layer TCL2 may be provided and/or formed on the second touch insulating layer T_INS2. The second touch conductive layer TCL2 may include the same material as the above-described first touch conductive layer TCL1 or include at least one material selected from the materials described as the material constituting the first touch conductive layer TCL1. The second touch conductive layer TCL2 may constitute a second layer of the plurality of touch electrodes. The second touch conductive layer TCL2 may be electrically connected to the first touch conductive layer TCL1 through a contact hole of the second touch insulating layer T_INS2. In order to prevent or reduce instances of the opening ratio of each of the sub-pixels SPX and light sensing pixels PSR being lowered, the second touch conductive layer TCL2 may be located on one surface of the second touch insulating layer T_INS2 to overlap with the bank BNK. That is, the second touch conductive layer TCL2 may be located on the one surface of the second touch insulating layer T_INS2 while avoiding the emission areas of the sub-pixels SPX and the light receiving areas of the light sensing pixels PSR so as to ensure image quality and light receiving amount.

The third touch insulating layer T_INS3 may be entirely provided and/or formed over the second touch conductive layer TCL2 and the second touch insulating layer T_INS2. The third touch insulating layer T_INS3 may include an organic layer, but embodiments according to the present disclosure are not limited thereto. According to some embodiments, the third touch insulating layer T_INS3 may be made of an inorganic layer, or have a structure in which organic and inorganic layers are alternatively stacked.

The selective light transmitting layer LBL may be located on the touch sensor layer TS. The selective light transmitting layer LBL may include a light blocking pattern LBP and a plurality of openings OP. The light blocking pattern LBP may use a material for blocking light emitted from the first to third light emitting elements LED1 to LED3. The light blocking pattern LBP may form a black matrix, using a material absorbing visible light, e.g., a metal material, a resin material including a pigment (e.g., carbon black or the like) or a dye, or the like. According to some embodiments, the light blocking pattern LBP may be a stacked structure of a red color filter, a green color filter, and a blue color filter. The light blocking pattern LBP may prevent or reduce color mixture between the first to third sub-pixels SPX1 to SPX3. The selective light transmitting layer LBL may have a thickness of about 5 μm in the third direction DR3, but embodiments according to the present disclosure are not limited thereto.

The selective light transmitting layer LBL may be covered by the overcoat layer OC. The overcoat layer OC may be made of a material having excellent light transmittance. The overcoat layer OC may planarize the top of the selective light transmitting layer. The overcoat layer OC may be made of an acrylic-based epoxy material, but embodiments according to the present disclosure are not limited thereto.

The window WD may be located on the top of the overcoat layer OC. The window WD may be a protective member located on the top of the overcoat layer OC to protect components of the display device (see “1” shown in FIG. 1). The window WD may be made of glass or plastic. When the window WD is made of glass, the window WD may be applied as Ultra Thin Glass (UTG) having a thickness of 0.1 mm or less so as to have flexible characteristics. However, embodiments according to the present disclosure are not limited thereto. The window WD may have a thickness of approximately 385 μm along the third direction DR3, but embodiments according to the present disclosure are not limited thereto. According to some embodiments, a polarizing member may be located between the window WD and the overcoat layer OC.

According to some embodiments, the third light emitting element LED3 overlapping with a (6-1)th opening OP6_1 of the selective light transmitting layer LBL may be located between a (2-1)th sub-light receiving element LRD2_1 (or the second light receiving element LRD2) overlapping with a (2-1)th opening OP2_1 (or a second opening OP2 of the selective light transmitting layer LBL and a (2-2)th light receiving element LRD2_2 (or the second light receiving element LRD2) overlapping with a (2-2)th opening OP2_2 (or the second opening OP2) of the selective light transmitting layer LBL.

As described with reference to FIGS. 9 to 11, as the (2-1)th opening OP2_1 is biased toward (or adjacent to) the (6-1)th opening OP6_1 and the (2-2)th opening OP2_2 is distant from the (6-1)th opening OP6_1, a center (see “CT1” shown in FIG. 11) of the (2-1)th opening OP2_1 and a center (see “CT3” shown in FIG. 11) of the (2-2)th opening OP2_2 may be moved to a right side on a plane and a section. At least a portion of a (2-1)th light receiving layer OPL2_1 of the (2-1)th sub-light receiving element LRD2_1 corresponding to the (2-1)th opening OP2_1 may overlap with the light blocking pattern LBP, and at least a portion of a (2-2)th light receiving layer OPL2_2 of the (2-2)th sub-light receiving element LRD2_2 corresponding to the (2-2)th opening OP2_2 may overlap with the light blocking pattern LBP. When a finger (see “F” shown in FIG. 8) of a user is in contact with a touch surface TUF (or display surface) of the window WD on the touch surface TUF, first light L1 emitted from the third light emitting element LED3 may be reflected by the finger F, and reflected second light L2 may reach the (2-1)th and (2-2)th sub-light receiving elements LRD2_1 and LRD2_2. As at least a portion of each of the (2-1)th and (2-2)th light receiving layers OPL2_1 and OPL2_2 overlaps with the light blocking pattern LBP, a portion L3 (hereinafter, referred to as “third light”) of the second light L2 may reach the light blocking pattern LBP and be absorbed by the light blocking pattern LBP. The amount of light introduced to each of the (2-1)th and (2-2)th light receiving layers OPL2_1 and OPL2_2 may be decreased. Accordingly, an amount of light incident onto the (2-1)th and (2-2)th light receiving layers OPL2_1 and OPL2_2 and an amount of light incident onto the first light receiving layer OPL1 of the first light receiving element LRD1 may substantially become similar or equal to each other.

As a (3-1)th opening OP3_1 is distant from a (6-2)th opening OP6_2 and a (3-2)th opening OP3_2 is biased toward (or adjacent to) the (6-2)th opening OP6_2, a center (see “CT2” shown in FIG. 11) of the (3-1)th opening OP3_1 and a center (see “CT4” shown in FIG. 11) of the (3-2)th opening OP3_2 may be moved to a left side on a plane and a section. At least a portion of a (3-1)th light receiving layer OPL3_1 of a (3-1)th sub-light receiving element LRD3_1 may overlap with the light blocking pattern LBP, and at least a portion of a (3-2)th light receiving layer OPL3_2 of a (3-2)th sub-light receiving element LRD3_2 may overlap with the light blocking pattern LBP. The amount of light introduced to each of the (3-1)th and (3-2)th light receiving layers OPL3_1 and OPL3_2 may be decreased. Accordingly, an amount of light incident onto the first light receiving layer OPL1 of the first light receiving element LRD1, which does not overlap with the light blocking pattern LBP, and an amount of light incident onto the (3-1)th and (3-2)th light receiving layers OPL3_1 and OPL3_2 may substantially become similar or equal to each other.

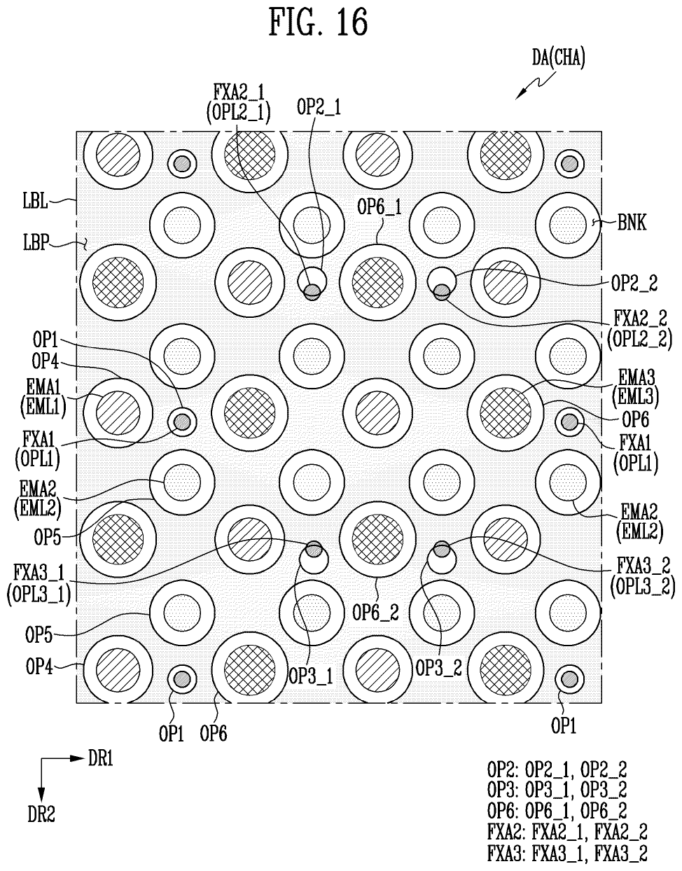

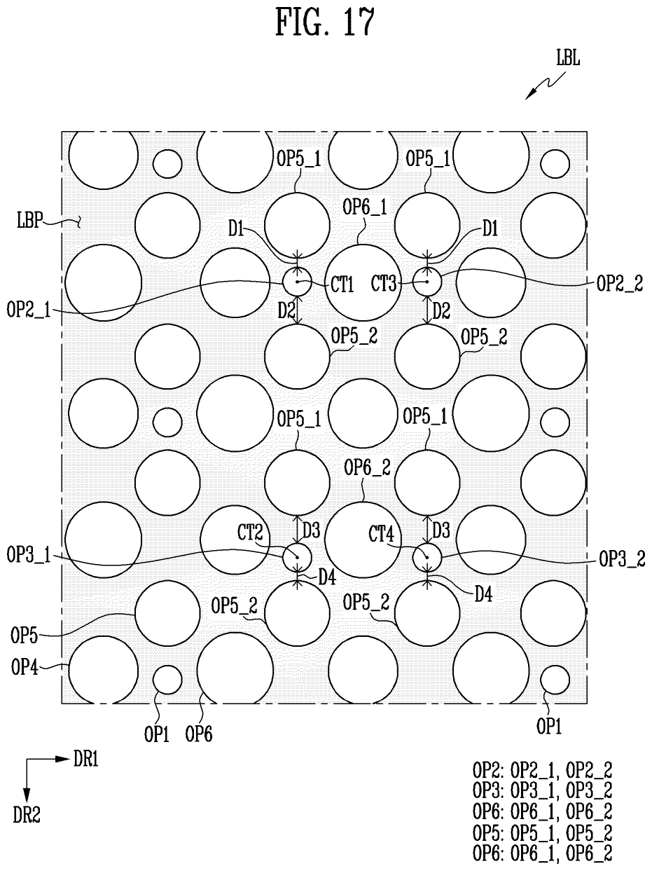

FIG. 16 is a schematic plan view illustrating one area of a display area DA of a display device according to some embodiments of the present disclosure. FIG. 17 is a schematic plan view illustrating a selective light transmitting layer LBL shown in FIG. 16.

In FIGS. 16 and 17, portions different from the portions of the above-described embodiments will be mainly described to avoid redundancy.

Referring to FIGS. 16 and 17, a first light emitting element (see “LED1” shown in FIG. 9), a second light emitting element (see “LED2” shown in FIG. 9), and a third light emitting element (see “LED3” shown in FIG. 9) may be provided in one area of the display area DA. In addition, a first light receiving element (see “LRD1” shown in FIG. 9), a second light receiving element (see “LRD2” shown in FIG. 9), and a third light receiving element (see “LRD3” shown in FIG. 9) may be provided in one area of the display area DA. According to some embodiments, the second light receiving element LRD2 may include a (2-1)th sub-light receiving element (see “LRD2_1” shown in FIG. 9) and a (2-2)th sub-light receiving element (see “LRD2_2” shown in FIG. 9). The third light receiving element LRD3 may include a (3-1)th sub-light receiving element (see “LRD3_1” shown in FIG. 9) and a (3-2)th sub-light receiving element (see “LRD3_2” shown in FIG. 9). The one area may be a capture area CHA in which a pattern of a fingerprint of a user is recognized using light incident onto light sensing pixels PSR.

A selective light transmitting layer LBL including openings overlapping with the first to third light emitting elements LED1 to LED3 and the first to third light receiving elements LRD1 to LRD3 may be located on the first to third light emitting elements LED1 to LED3 and the first to third light receiving elements LRD1 to LRD3. The selective light transmitting layer LBL may include a light blocking pattern LBP, a first opening OP1, a second opening OP2, a third opening OP3, a fourth opening OP4, a fifth opening OP5, and a sixth opening OP6.

The second opening OP2 may include a (2-1)th opening OP2_1 overlapping with the (2-1)th sub-light receiving element LRD2_1 and a (2-2)th opening OP2_2 overlapping with the (2-2)th sub-light receiving element LRD2_2. The third opening OP3 may include a (3-1)th opening OP3_1 overlapping the (3-1)th sub-light receiving element LRD3_1 and a (3-2)th opening OP3_2 overlapping with (3-2)th sub-light receiving element LRD3_2.

According to some embodiments, one fifth opening OP5 may be located at an upper side of each of the (2-1)th, (2-2)th, (3-1)th, and (3-2)th openings OP2_1, OP2_2, OP3_1, and OP3_2 in the second direction DR2, and another fifth opening OP5 may be located at a lower side of each of the (2-1)th, (2-2)th, (3-1)th, and (3-2)th openings OP2_1, OP2_2, OP3_1, and OP3_2 in the second direction DR2. For convenience of description, the one fifth opening OP5 located at the upper side of each of the (2-1)th, (2-2)th, (3-1)th, and (3-2)th openings OP2_1, OP2_2, OP3_1, and OP3_2 will be referred to as a (5-1)th opening OP5_1, and the another fifth opening OP5 located at the lower side of each of the (2-1)th, (2-2)th, (3-1)th, and (3-2)th openings OP2_1, OP2_2, OP3_1, and OP3_2 will be referred to as a (5-2)th opening OP5_2.

The (5-1)th opening OP5_1 may overlap with one second light emitting element LED2 located at an upper side of a light receiving element overlapping with each of the (2-1)th, (2-2)th, (3-1)th, and (3-2)th openings OP2_1, OP2_2, OP3_1, and OP3_2. The (5-2)th opening OP5_2 may overlap with another second light emitting element LED2 located at a lower side of the light receiving element overlapping with each of the (2-1)th, (2-2)th, (3-1)th, and (3-2)th openings OP2_1, OP2_2, OP3_1, and OP3_2.

In a plan view, a first distance D1 between each of the (2-1)th and (2-2)th openings OP2_1 and OP2_2 and a corresponding (5-1)th opening OP5_1 may be smaller than a second distance D2 between each of the (2-1)th and (2-2)th openings OP2_1 and OP2_2 and a corresponding (5-2)th opening OP5_2. For example, each of the (2-1)th and (2-2)th openings OP2_1 and OP2_2 may be located in the light blocking pattern LBP to be biased toward the (5-1)th opening OP5_1 and to be distant from the (5-2)th opening OP5_2. That is, the (2-1)th and (2-2)th openings OP2_1 and OP2_2 may be located more adjacent to the (5-1)th opening OP5_1 than the (5-2)th opening OP5_2. A center CT1 of the (2-1)th opening OP2_1 and a center CT3 of the (2-2)th opening OP2_2 may be located to be biased toward (or adjacent to) the (5-1)th opening OP5_1 as compared with the (5-2)th opening OP5_2.

In a plan view, a third distance D3 between each of the (3-1)th and (3-2)th openings OP3_1 and OP3_2 and a corresponding (5-1)th opening OP5_1 may be greater than a fourth distance D4 between each of the (3-1)th and (3-2)th openings OP3_1 and OP3_2 and a corresponding (5-2)th opening OP5_2. For example, each of the (3-1)th and (3-2)th openings OP3_1 and OP3_2 may be located in the light blocking pattern LBP to be biased toward the (5-2)th opening OP5_2 and to be distant from the (5-1)th opening OP5_1. That is, the (3-1)th and (3-2)th openings OP3_1 and OP3_2 may be located more adjacent to the (5-2)th opening OP5_2 than the (5-1)th opening OP5_1. A center CT2 of the (3-1)th opening OP3_1 and a center CT4 of the (3-2)th opening OP3_2 may be located to be biased toward (or adjacent to) the (5-2)th opening OP5_2 as compared with the (5-1)th opening OP5_1.

According to some embodiments, the first distance D1 and the fourth distance D4 may be the same, and the second distance D2 and the third distance D3 may be the same. However, embodiments according to the present disclosure are not limited thereto.

According to some embodiments, a center of the second opening OP2 and a center of the third opening OP3 may be shifted in directions opposite to each other. For example, the center CT1 of the (2-1)th opening OP2_1 and the center CT2 of the (3-1)th opening OP3_1 may be shifted in directions opposite to each other along the second direction DR2. The center CT3 of the (2-2)th opening OP2_2 and the center CT4 of the (3-2)th opening OP3_2 may be shifted in directions opposite to each other along the second direction DR2. The center CT1 of the (2-1)th opening OP2_1 may be shifted in the opposite direction of the second direction DR2, and the center CT2 of the (3-1)th opening OP3_1 may be shifted in the second direction DR2. The center CT3 of the (2-2)th opening OP2_2 may be shifted in the opposite direction of the second direction DR2, and the center CT4 of the (3-2)th opening OP3_2 may be shifted in the second direction DR2. For example, the center CT1 of the (2-1)th opening OP2_1 and the center CT3 of the (2-2)th opening OP2_2 may be shifted to an upper side along the second direction DR2, and the center CT2 of the (3-1)th opening OP3_1 and the center CT4 of the (3-2)th opening OP3_2 may be shifted to a lower side along the second direction DR2.

As described above, when the center CT1 of the (2-1)th opening OP2_1 is shifted to the upper side, at least a portion of a (2-1)th light receiving layer OPL2_1 of the (2-1)th sub-light receiving element LRD2_1 may overlap with the light blocking pattern LBP. When the center CT3 of the (2-2)th opening OP2_2 is shifted to the upper side, at least a portion of a (2-2)th light receiving layer OPL2_2 of the (2-2)th sub-light receiving element LRD2_2 may overlap with the light blocking pattern LBP. In addition, when the center CT2 of the (3-1)th opening OP3_1 is shifted to the lower side, at least a portion of a (3-1)th light receiving layer OPL3_1 of the (3-1)th sub-light receiving element LRD3_1 may overlap with the light blocking pattern LBP. When the center CT4 of the (3-2)th opening OP3_2 is shifted to the lower side, at least a portion of a (3-2)th light receiving layer OPL3_2 of the (3-2)th sub-light receiving element LRD3_2 may be overlap with the light blocking pattern LBP.

As at least a portion of each of the (2-1)th and (2-2)th light receiving layers OPL2_1 and OPL2_2 overlaps with the light blocking pattern LBP, an amount of light reflected from the selective light transmitting layer LBL to be incident onto the (2-1)th and (2-2)th light receiving layers OPL2_1 and OPL2_2 through a corresponding second opening OP2 may be decreased. The amount of light incident onto the (2-1)th and (2-2)th light receiving layers OPL2_1 and OPL2_2 may be substantially similar or equal to an amount of light incident onto a first light receiving layer OPL1 of the first light receiving element LRD1. As at least a portion of each of the (3-1)th and (3-2)th light receiving layers OPL3_1 and OPL3_2 overlaps with the light blocking pattern LBP, an amount of light reflected from the selective light transmitting layer LBL to be incident onto the (3-1)th and (3-2)th light receiving layers OPL3_1 and OPL3_2 through a corresponding third opening OP3 may be decreased. The amount of light incident onto the (3-1)th and (3-2)th light receiving layers OPL3_1 and OPL3_2 may be substantially similar or equal to the amount of light incident onto the first light receiving layer OPL1 of the first light receiving element LRD1.

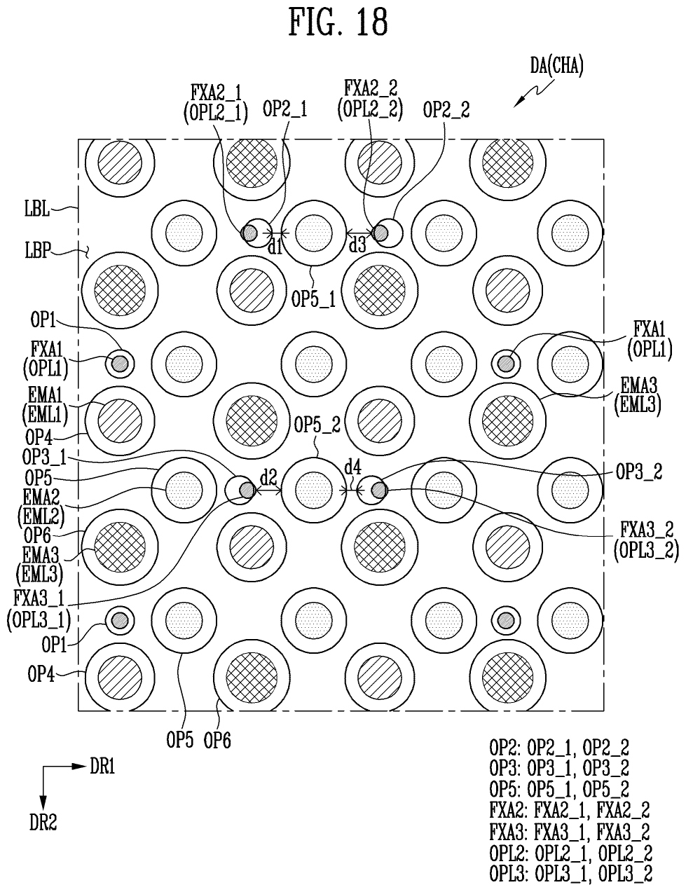

FIG. 18 is a schematic plan view illustrating one area of a display area DA of a display device according to some embodiments of the present disclosure.

In FIG. 18, portions different from the portions of the above-described embodiments will be mainly described to avoid redundancy.

Referring to FIG. 18, a selective light transmitting layer LBL may be provided, which includes a light blocking pattern LBP and first to sixth openings OP1 to OP6.

The first opening OP1 may overlap with a first light receiving layer OPL1 of a first light receiving element (see “LRD1” shown in FIG. 9), the second opening OP2 may overlap with a second light receiving layer OPL2 of a second light receiving element (see “LRD2” shown in FIG. 9), the third opening OP3 may overlap with a third light receiving layer OPL3 of a third light receiving element (see “LRD3” shown in FIG. 9), the fourth opening OP4 may overlap with a first light emitting layer EML1 of a first light emitting element (see “LED1” shown in FIG. 9), the fifth opening OP5 may overlap with a second light emitting layer EML2 of a second light emitting element (see “LED2” shown in FIG. 9), and the sixth opening OP6 may overlap with a third light emitting layer EML3 of a third light emitting element (see “LED3” shown in FIG. 9).

First light receiving element LRD1 (or first light sensing pixels (see “PSR1” shown in FIG. 9)) may be arranged with three second light emitting elements LED2 interposed therebetween in the first direction DR1. For example, three second light emitting elements LED2 may be located between two first light receiving elements LRD1 adjacent to each other in the first direction DR1. In addition, first light receiving elements LRD1 may be arranged with two light emitting elements (e.g., a first light emitting element LED1 and a third light emitting element LED3) interposed therebetween in the second direction DR2. For example, two light emitting elements, e.g., a first light emitting element LED1 and a third light emitting element LED3 may be located between two first light receiving elements LRD1 adjacent to each other in the second direction DR2.

The second light receiving element LRD2 may include a (2-1)th sub-light receiving element (see “LRD2_1” shown in FIG. 9) and a (2-2)th sub-light receiving element (see “LRD2_2” shown in FIG. 9), which are arranged side by side in the first direction DR1. The third light receiving element LRD3 may include a (3-1)th sub-light receiving element (see “LRD3_1” shown in FIG. 9) and a (3-2)th sub-light receiving element (see “LRD3_2” shown in FIG. 9), which are arranged side by side in the first direction DR1. The (2-1)th sub-light receiving element LRD2_1 and the (2-2)th sub-light receiving element LRD2_2 may be electrically connected to the same sensor circuit (see “SC” shown in FIG. 6), and the (3-1)th sub-light receiving element LRD3_1 and the (3-2)th sub-light receiving element LRD3_2 may be electrically connected to the same sensor circuit.

In a plan view, the (2-1)th sub-light receiving element LRD2_1 and the (3-1)th sub-light receiving element LRD3_1 may be located on the same column in the second direction DR2, and the (2-2)th sub-light receiving element LRD2_2 and the (3-2)th sub-light receiving element LRD3_2 may be located on the same column in the second direction DR2. Two light emitting elements, e.g., one first light emitting element LED1 and one third light emitting element LED3 may be located between the (2-1)th sub-light receiving element LRD2_1 and the (3-1)th sub-light receiving element LRD3_1. Two light emitting elements, e.g., another first light emitting element LED1 and another third light emitting element LED3 may be located between the (2-2)th sub-light receiving element LRD2_2 and the (3-2)th sub-light receiving element LRD3_2.

One second light emitting element LED2 may be located between the (2-1)th sub-light receiving element LRD2_1 and the (2-2)th sub-light receiving element LRD2_2, and another second light emitting element LED2 may be located between the (3-1)th sub-light receiving element LRD3_1 and the (3-2)th sub-light receiving element LRD3_2.

According to some embodiments, the second opening OP2 may include a (2-1)th opening OP2_1 and a (2-2)th opening OP2_2, and the third opening OP3 may include a (3-1)th opening OP3_1 and a (3-2)th opening OP3_2. One fifth opening OP5 may be located between the (2-1)th opening OP2_1 and the (2-2)th opening OP2_2 in the first direction DR1, and another fifth opening OP5 may be located between the (3-1)th opening OP3_1 and the (3-2)th opening OP3_2 in the first direction DR1. For convenience of description, the one fifth opening OP5 located between the (2-1)th opening OP2_1 and the (2-2)th opening OP2_2 will be referred to as a (5-1)th opening OP5_1, and the another fifth opening OP5 located between the (3-1)th opening OP3_1 and the (3-2)th opening OP3_2 will be referred to as a (5-2)th opening OP5_2.

The (2-1)th opening OP2_1 may overlap with the (2-1)th sub-light receiving element LRD2_1, the (2-2)th opening OP2_2 may overlap with the (2-2)th sub-light receiving element LRD2_2, the (3-1)th opening OP3_1 may overlap with the (3-1)th sub-light receiving element LRD3_1, and the (3-2)th opening OP3_2 may overlap with the (3-2)th sub-light receiving element LRD3_2.

In a plan view, a first shortest distance d1 between the (2-1)th opening OP2_1 and the (5-1)th opening OP5_1 may be smaller than a third shortest distance d3 between the (2-2)th opening OP2_2 and the (5-1)th opening OP5_1. For example, the (2-1)th opening OP2_1 may be located in the light blocking pattern LBP to be biased toward the (5-1)th opening OP5_1 in the first direction DR1, and the (2-2)th opening OP2_2 may be located in the light blocking pattern LBP to be distant from the (5-1)th opening OP5_1 (or to be biased toward another fifth opening OP5 adjacent to the (5-1)th opening OP5_1). That is, the (2-1)th opening OP2_1 may be located more adjacent to the (5-1)th opening OP5_1 than the (2-2)th opening OP2_2. At least a portion of a (2-1)th light receiving layer OPL2_1 of the (2-1)th sub-light receiving element LRD2_1, which corresponds to the (2-1)th opening OP2_1, may overlap with the light blocking pattern LBP, and at least a portion of a (2-2)th light receiving layer OPL2_2 of the (2-2)th sub-light receiving element LRD2_2, which corresponds to the (2-2)th opening OP2_2, may overlap with the light blocking pattern LBP.

In a plan view, a shortest distance d2 between the (3-1)th opening OP3_1 and the (5-2)th opening OP5_2 may be greater than a fourth shortest distance d4 between the (3-2)th opening OP3_2 and the (5-2)th opening OP5_2. For example, the (3-1)th opening OP3_1 may be located in the light blocking pattern LBP to be distant from the (5-2)th opening OP5_2 (or to be biased toward another fifth opening OP5 adjacent to the (5-2)th opening OP5_2) in the first direction DR1, and the (3-2)th opening OP3_2 may be located in the light blocking pattern LBP to be biased toward the (5-2)th opening OP5_2. That is, the (3-2)th opening OP3_2 may be located more adjacent to the (5-2)th opening OP5_2 than the (3-1)th opening OP3_1. At least a portion of a (3-1)th light receiving layer OPL3_1 of the (3-1)th sub-light receiving element LRD3_1, which corresponds to the (3-1)th opening OP3_1, may overlap with the light blocking pattern LBP, and at least a portion of a (3-2)th light receiving layer OPL3_2 of the (3-2)th sub-light receiving element LRD3_2, which corresponds to the (3-2)th opening OP3_2, may overlap with the light blocking pattern LBP.

As at least a portion of each of the (2-1)th and (2-2)th light receiving layers OPL2_1 and OPL2_2 overlaps with the light blocking pattern LBP, an amount of light incident onto the (2-1)th and (2-2)th light receiving layers OPL2_1 and OPL2_2 through a corresponding second opening OP2 may be decreased. The amount of light incident onto the (2-1)th and (2-2)th light receiving layers OPL2_1 and OPL2_2 may be substantially similar or equal to an amount of light incident onto the first light receiving layer OPL1 of the first light receiving element LRD1.

As at least a portion of each of the (3-1)th and (3-2)th light receiving layers OPL3_1 and OPL3_2 overlaps with the light blocking pattern LBP, an amount of incident onto the (3-1)th and (3-2)th light receiving layers OPL3_1 and OPL3_2 through a corresponding third opening OP3 may be decreased. The amount of incident onto the (3-1)th and (3-2)th light receiving layers OPL3_1 and OPL3_2 may be substantially similar or equal to an amount of light incident onto the first light receiving layer OPL1 of the first light receiving element LRD1.

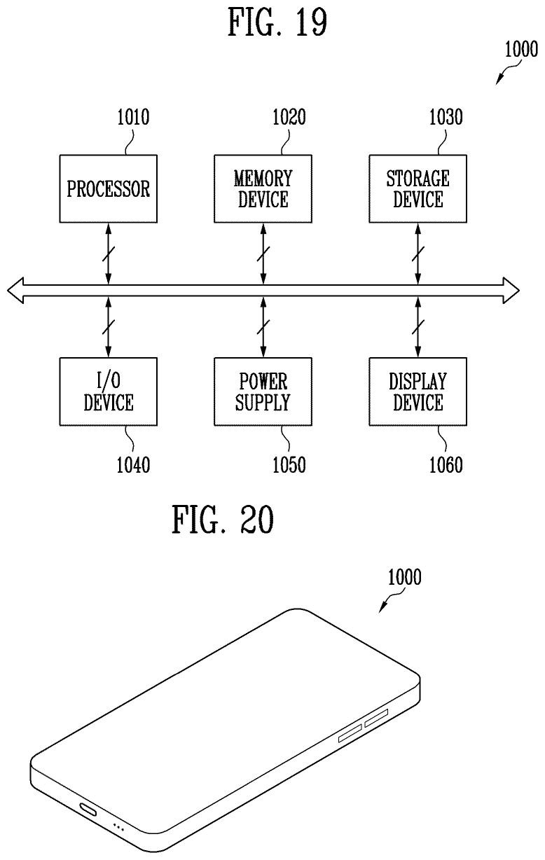

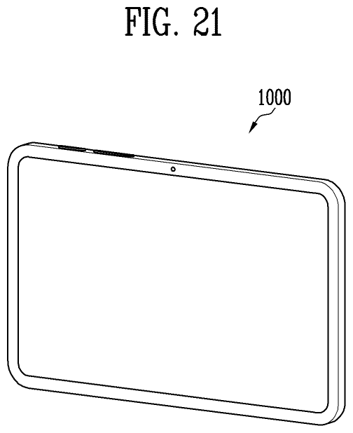

FIG. 19 is a schematic block diagram illustrating an electronic device 1000 according to some embodiments of the present disclosure. FIG. 20 is a schematic view illustrating an example in which the electronic device 1000 shown in FIG. 19 is implemented as a smartphone. FIG. 21 is a schematic view illustrating an example in which the electronic device 1000 shown in FIG. 19 is implemented as a tablet PC.

Referring to FIGS. 19 to 21, the electronic device 1000 may include a processor 1010, a memory device 1020, a storage device 1030, an input/output (I/O) device 1040, a power supply, 1050, and a display device 1060. The display device 1060 may be the display device 2 shown in FIGS. 1 and 2. Also, the electronic device 1000 may further include several ports capable of communicating with a video card, a sound card, a memory card, a USB device, and the like, or communicating with other systems. According to some embodiments, as shown in FIG. 20, the electronic device 1000 may be implemented as a smartphone. According to some embodiments, as shown in FIG. 21, the electronic device 1000 may be implemented as a tablet PC. However, this is merely illustrative, and the electronic device 1000 is not limited to the above-described example. For example, the electronic device 1000 may be implemented as a mobile phone, a video phone, a smart pad, a smart watch, a vehicle navigation system, a computer monitor, a notebook computer, a head mounted display device, or the like.

The processor 1010 may perform specific calculations or tasks. According to some embodiments, the processor 1010 may be a microprocessor, a central processing unit, an application processor, or the like. The processor 1010 may be connected to other components through an address bus, a control bus, a data bus, and the like. According to some embodiments, the processor 1010 may be connected to an extension bus such as a peripheral component interconnect (PCI) bus.

The memory device 1020 may store data necessary for an operation of the electronic device 1000. For example, the memory device 1020 may include a nonvolatile memory device such as an Erasable Programmable Read-Only Memory (EPROM) device, an Electrically Erasable Programmable Read-Only Memory (EEPROM) device, a flash memory device, a Phase Change Random Access Memory (PRAM) device, a Resistance Random Access Memory (RRAM) device, a Nano Floating Gate Memory (NFGM) device, a Polymer Random Access Memory (PoRAM) device, a Magnetic Random Access Memory (MRAM) device, or a Ferroelectric Random Access Memory (FRAM) device, and/or a volatile memory device such as a Dynamic Random Access Memory (DRAM) device, a Static Random Access Memory (SRAM) device, or a mobile DRAM device.

The storage device 1030 may include a Solid State Drive (SSD), a Hard Disk Drive (HDD), a Compact Disc Read Only Memory (CD-ROM), and the like.

The I/O device 1040 may include an input means such as a keyboard, a keypad, a touch screen, or a mouse, and an output means such as a speaker or a printer. According to some embodiments, the display device 1060 may be included in the I/O device 1040.

The power supply 1050 may supply power necessary for an operation of the electronic device 1000. For example, the power supply 1050 may be a power management integrated circuit (PMIC).

The display device 1060 may display an image corresponding to visual information of the electronic device 1000. The display device 1060 may be an organic light emitting display device or a quantum dot light emitting display device, but embodiments according to the present disclosure are not limited thereto. The display device 1060 may be connected to other components through the buses or another communication link.

According to some embodiments of the present disclosure, a first opening of a selective light transmitting layer, which overlaps with first and second sub-light receiving elements connected to one sensor circuit in one area of a display area, and a second opening of the selective light transmitting layer, which overlaps with third and fourth sub-light receiving elements which are connected to another sensor circuit and are located on the same column as the first and second sub-light receiving elements, are shifted in directions opposite to each other, thereby reducing or preventing a variation in light receiving amount in the one area.

According to some embodiments of the present disclosure, a display device may have relatively improved reliability and an electronic device having the same.

Aspects of some embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims, and their equivalents.

What is claimed is:

1. A display device comprising:
a substrate;
an element layer on the substrate, the element layer including a first light receiving element including a first light receiving layer, a second light receiving element including a second light receiving layer, and a third light receiving element including a third light receiving layer; and
a selective light transmitting layer on the element layer, the selective light transmitting layer including openings forming an advancing path of light incident onto the first to third light receiving elements and a light blocking pattern between the openings,
wherein, in a plan view, at least a portion of the light blocking pattern overlaps with the second light receiving layer and the third light receiving layer.

2. The display device of claim 1, wherein the second light receiving element includes a first sub-light receiving element and a second sub-light receiving element, which are electrically connected to each other through a first routing line extending in a first direction,
wherein the third light receiving element includes a third sub-light receiving element and a fourth sub-light receiving element, which are electrically connected to each other through a second routing line extending in the first direction, and
wherein the first sub-light receiving element and the third sub-light receiving element are located in a same column in a second direction, and
the second sub-light receiving element and the fourth sub-light receiving element are located in a same column in the second direction.

3. The display device of claim 2, wherein the element layer further includes first light emitting elements each including a first light emitting layer, second light emitting elements each including a second light emitting layer, and third light emitting elements each including a third light emitting layer,
wherein, in the plan view, at least one third light emitting element among the third light emitting elements is between the first sub-light receiving element and the second sub-light receiving element in the first direction,
wherein, in the plan view, at least another third light emitting element among the third light emitting elements is between the third sub-light receiving element and the fourth sub-light receiving element in the first direction, and
wherein the at least one third light emitting element and the at least another third light emitting element are in a same column in the second direction.

4. The display device of claim 3, wherein the openings include:
a first opening corresponding to the first light receiving element;
a second opening corresponding to the second light receiving element;
a third opening corresponding to the third light receiving element;
a fourth opening corresponding to each of the first light emitting elements;
a fifth opening corresponding to each of the second light emitting elements; and
a sixth opening corresponding to each of the third light emitting elements,
wherein the second opening includes a (2-1)th opening corresponding to the first sub-light receiving element and a (2-2)th opening corresponding to the second sub-light receiving element,
wherein the third opening includes a (3-1)th opening corresponding to the third sub-light receiving element and a (3-2)th opening corresponding to the fourth sub-light receiving element, and
wherein the sixth opening includes a (6-1)th opening corresponding to the at least one third light emitting element and a (6-2)th opening corresponding to the at least another third light emitting element.

5. The display device of claim 4, wherein, in the plan view, a first shortest distance between the (2-1)th opening and the (6-1)th opening is smaller than a second shortest distance between the (3-1)th opening and the (6-2)th opening, and
wherein, in the plan view, a third shortest distance between the (2-2)th opening and the (6-1)th opening is greater than a fourth shortest distance between the (3-2)th opening and the (6-2)th opening.

6. The display device of claim 5, wherein the first shortest distance and the fourth shortest distance are equal, and
the second shortest distance and the third shortest distance are equal.

7. The display device of claim 5, wherein, in the plan view, the (2-1)th opening is closer to the (6-1)th opening than the (2-2)th opening, and
wherein, in the plan view, the (3-2)th opening is closer to the (6-2)th opening than the (3-1)th opening.

8. The display device of claim 5, wherein, in the plan view, an edge of the (2-1)th opening is located inwardly of an edge of the (3-1)th opening in the first direction, and
wherein, in the plan view, an edge of the (2-2)th opening is located inwardly of an edge of the (3-2)th opening in the first direction.

9. The display device of claim 8, wherein, the second opening and the third opening have a circular shape, and
wherein, in the plan view, a center of the second opening and a center of the third opening are shifted in directions opposite to each other along the first direction.

10. The display device of claim 4, wherein, in the plan view, each of the first to fourth sub-light receiving elements is between two adjacent second light emitting elements among the second light emitting elements in the second direction, and
wherein the two second light emitting elements include a (2-1)th light emitting element located at an upper side of each of the first to fourth sub-light receiving elements in the second direction and a (2-2)th light emitting element located at a lower side of each of the first to fourth sub-light receiving elements in the second direction.

11. The display device of claim 10, wherein the fifth opening includes a (5-1)th opening corresponding to the (2-1)th light emitting element and a (5-2)th opening corresponding to the (2-2)th light emitting element,
wherein, in the plan view, a first distance between each of the (2-1)th and (2-2)th openings and the (5-1)th opening in the second direction is smaller than a second distance between each of the (2-1)th and (2-2)th openings and the (5-2)th opening in the second direction, and
wherein, in the plan view, a third distance between each of the (3-1)th and (3-2)th openings and the (5-1)th opening in the second direction is greater than a fourth distance between each of the (3-1)th and (3-2)th openings and the (5-2)th opening in the second direction.

12. The display device of claim 11, wherein the first distance and the fourth distance are equal, and
the second distance and the third distance are equal.

13. The display device of claim 11, wherein, in the plan view, each of the (2-2)th and (2-2)th openings is closer to the (5-1)th opening than the (5-2)th opening, and
wherein, in the plan view, each of the (3-1)th and (3-2)th openings is closer to the (5-2)th opening than the (5-1)th opening.

14. The display device of claim 2, wherein the element layer further includes first light emitting elements each including a first light emitting layer, second light emitting elements each including a second light emitting layer, and third light emitting elements each including a third light emitting layer,
wherein, in the plan view, at least one second light emitting element among the second light emitting elements is between the first sub-light receiving element and the second sub-light receiving element in the first direction,
wherein, in the plan view, at least another second light emitting element among the second light emitting elements is between the third sub-light receiving element and the fourth sub-light receiving element in the first direction, and
wherein the at least one second light emitting element and the at least another second light emitting element are in a same column in the second direction.

15. The display device of claim 14, wherein the openings include:
a first opening corresponding to the first light receiving element;
a second opening corresponding to the second light receiving element;
a third opening corresponding to the third light receiving element;
a fourth opening corresponding to each of the first light emitting elements;
a fifth opening corresponding to each of the second light emitting elements; and
a sixth opening corresponding to each of the third light emitting elements,
wherein the second opening includes a (2-1)th opening corresponding to the third sub-light receiving element and a (2-2)th opening corresponding to the second sub-light receiving element,
wherein the third opening includes a (3-1)th opening corresponding to the third sub-light receiving element and a (3-2)th opening corresponding to the fourth sub-light receiving element, and
wherein the fifth opening includes a (5-1)th opening corresponding to the at least one second light emitting element and a (5-2)th opening corresponding to the at least another second light emitting element.

16. The display device of claim 15, wherein, in the plan view, a first shortest distance between the (2-1)th opening and the (5-1)th opening is smaller than a second shortest distance between the (3-1)th opening and the (5-2)th opening, and
wherein, in the plan view, a third shortest distance between the (2-2)th opening and the (5-1)th opening is greater than a fourth shortest distance between the (3-2)th opening and the (5-2)th opening.

17. The display device of claim 1, wherein, in the plan view, the first light receiving layer does not overlap with the light blocking pattern.

18. An electronic device comprising:
a processor configured to provide input image data to a display device; and
the display device configured to display an image, based on the input image data,
wherein the display device includes:
a substrate;
an element layer on the substrate, the element layer including a first light receiving element including a first light receiving layer, a second light receiving element including a second light receiving layer, and a third light receiving element including a third light receiving layer; and
a selective light transmitting layer on the element layer, the selective light transmitting layer including openings forming an advancing path of light incident onto the first to third light receiving elements and a light blocking pattern between the openings,
wherein, in a plan view, at least a portion of the light blocking pattern overlaps with the second light receiving layer and the third light receiving layer,
wherein the second light receiving layer includes a first sub-light receiving element and a second sub-light receiving element, which are electrically connected to each other through a first routing line extending in a first direction,
wherein the third light receiving layer includes a third sub-light receiving element and a fourth sub-light receiving element, which are electrically connected to each other through a second routing line extending in the first direction, and
wherein the first sub-light receiving element and the third sub-light receiving element are in a same column in a second direction, and
the second sub-light receiving element and the fourth sub-light receiving element are in a same column in the second direction.

19. The electronic device of claim 18, wherein the openings include:
a first opening corresponding to the first light receiving element;
a second opening corresponding to the second light receiving element; and
a third opening corresponding to the third light receiving element, and
wherein, in the plan view, a center of the second opening and a center of the third opening are shifted in directions opposite to each other along the first direction.

20. The electronic device of claim 18, wherein, in the plan view, the first light receiving layer does not overlap with the light blocking pattern.
